(19) United States
(12) Patent Application Publication
(10) Pub. No.: US 2025/0136805 A1
(43) Pub. Date: May 1, 2025

(54) COPOLYMER, METHOD OF PREPARING THE SAME, RESIN COMPOSITION, AND PRODUCT OF THE SAME

(71) Applicant: ELITE ELECTRONIC MATERIAL (ZHONGSHAN) CO., LTD., Zhongshan City (CN)

(72) Inventors: Xinwen WANG, Zhongshan City (CN); Zhilong HU, Zhongshan City (CN); Xiang XIONG, Zhongshan City (CN); Xiangnan LI, Zhongshan City (CN)

(21) Appl. No.: 18/535,684

(22) Filed: Dec. 11, 2023

(30) Foreign Application Priority Data
Oct. 30, 2023 (CN) 2023114278685

(51) Int. Cl. C08L 43/04; B32B 5/26; C08F 230/08; C08J 5/24; C08L 53/02; H05K 1/03

(52) U.S. Cl. CPC C08L 43/04; B32B 5/26; C08F 230/085; C08J 5/244; C08L 53/025; H05K 1/0353; B32B 2250/05; B32B 2250/40; B32B 2260/023; B32B 2260/046; B32B 2262/101; B32B 2307/204; B32B 2307/308; C08F 2800/20; C08J 2343/04; C08J 2353/02; C08J 2409/06; C08J 2423/16; C08J 2453/02; C08J 2471/12; C08L 2205/03; H05K 2201/012

(57) ABSTRACT

Disclosed is a copolymer, including a structural unit formed from phenylvinylsilane and vinyl-containing compound A; the raw materials of the copolymer include phenylvinylsilane and vinyl-containing compound A; based on a total weight of phenylvinylsilane and the vinyl-containing compound A being 100 parts by weight, phenylvinylsilane is 80 to 98 parts by weight, and vinyl-containing compound A is 2 to 20 parts by weight. Also disclosed is a method of preparing the copolymer, including performing a reaction of 80 to 98 parts by weight of phenylvinylsilane and 2 to 20 parts by weight of vinyl-containing compound A. Also disclosed is a resin composition including the copolymer, a method of preparing the resin composition, a use of the resin composition in preparing a product, and a product of which at least a portion is made from the resin composition.

### CROSS-REFERENCE TO RELATED APPLICATIONS

This application claims the priority to Chinese Patent Application No. 202311427868.5, filed to China National Intellectual Property Administration on Oct. 30, 2023, which is incorporated by reference herein in its entirety.

### FIELD

The present application relates to the field of polymers, and particularly to a copolymer, a method of preparing the same, a resin composition, and a product of the same such as a prepreg, a resin film, a laminate, a printed circuit board, or a cured insulator.

### BACKGROUND

In recent years, electronic technology has been developing towards higher integration, lower power consumption, and higher performance, thus placing higher demands on high-performance electronic materials.

With the development of information processing in electronic products such as mobile communication, servers, and cloud storage trending towards high-frequency and high-speed digitization of signal transmission, low dielectric resin materials have become the main development direction of high-frequency and high-speed substrates. In the manufacture of materials for copper clad laminate, the raw material phenylvinylsilane is easy to be volatilized due to high-temperature heating in the material processing section, which not only results in the waste of expensive raw materials when used directly, but also causes changes in the properties of materials for copper clad laminate and fails to meet the requirements of the characteristics.

### SUMMARY

Therefore, the inventors have conducted studies to reduce volatility and improve the overall performance of materials for copper clad laminate, such as improvement in one or more characteristics such as glass transition temperature, peeling strength of copper foil, dielectric constant, or dissipation factor.

In view of the problems encountered in the related art, particularly the inability of existing materials to meet the requirements of one or more of the above-mentioned characteristics, a primary object of some embodiments of the present application is to provide a copolymer and a method of preparing the same, a resin composition comprising the copolymer, a use of the resin composition in preparing a product, and a product of which at least a portion is made from the resin composition that can overcome at least one of the above-mentioned technical problems.

In one aspect, the present application provides a copolymer, comprising a structural unit formed from phenylvinylsilane and vinyl-containing compound A,
wherein raw materials of the copolymer comprise phenylvinylsilane and vinyl-containing compound A; based on a total weight of phenylvinylsilane and the vinyl-containing compound A being 100 parts by weight, phenylvinylsilane is 80 to 98 parts by weight, and the vinyl-containing compound A is 2 to 20 parts by weight; and
wherein, the phenylvinylsilane has a structure of formula (1) or formula (2), and the vinyl-containing compound A has a structure of formula (3),

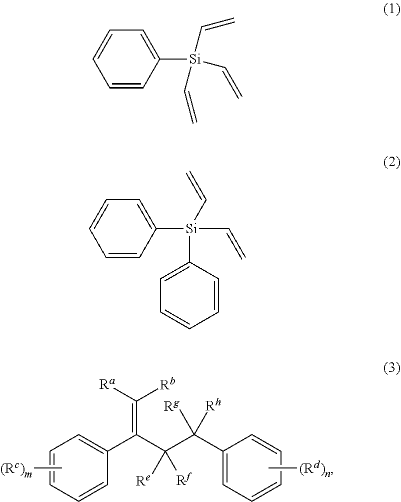

and
wherein,
   R^{a}, R^{b}, R^{c}, and R^{d} are each independently H or a monovalent organic group;
   m and n are each independently an integer from 0 to 5; and
   R^{e}, R^{f}, R^{g}, and R^{h} are each independently H or monovalent alkyl having 1 to 4 carbon atoms.

In one aspect, the present application provides a method of preparing the copolymer, comprising performing a reaction of 80 to 98 parts by weight of phenylvinylsilane and 2 to 20 parts by weight of vinyl-containing compound A.

In one aspect, the present application provides a resin composition, comprising the copolymer, a vinyl-containing polyphenylene ether resin, and a polyolefin resin.

In one aspect, the present application provides a method of preparing the resin composition, comprising mixing the copolymer, a vinyl-containing polyphenylene ether resin, and a polyolefin resin.

In one aspect, the present application provides a use of the resin composition in preparing a product comprising a prepreg, a resin film, a laminate, a printed circuit board, or a cured insulator.

In one aspect, the present application provides a product, comprising a prepreg, a resin film, a laminate, a printed circuit board, or a cured insulator, where at least a portion of the product is made from the resin composition.

Some embodiments of the present application provide products that can be improved in one or more aspects, such as glass transition temperature, peeling strength of copper foil, dielectric constant, or dissipation factor.

### BRIEF DESCRIPTION OF THE DRAWINGS

FIG. 1 is infrared spectrograms of copolymer 3, phenyltrivinylsilane, and 2,4-diphenyl-4-methyl-1-pentene.

FIG. 2 is ¹H NMR spectra of copolymer 3, phenyltrivinylsilane, and 2,4-diphenyl-4-methyl-1-pentene.

FIG. 3 is a gel permeation chromatogram of copolymer 3.

### DETAILED DESCRIPTION

In order to further describe the technical means adopted by the present application to achieve the intended objective and functions, the following describes specific embodiments, structures, features, and functions of the present application in detail with reference to the accompanying drawings and preferred embodiments.

### Terms and Definitions

The terms used herein (including technical and scientific terms) have the same meaning as those generally understood by those skilled in the art. If otherwise specified, the terms defined herein shall prevail. Singular terms used herein refer to one or more. For instance, “an element” or “one element” refer to one or more elements. “A plurality of” used herein refers to at least two.

“Include”, “comprise”, “have” and “contain” used herein are all open-ended transitional phrases (i.e., they may also include other unlisted elements). “Consist of” and “composed of” used herein this article are all close-ended transitional phrases.

Numerical ranges used herein include all possible subranges and all individual numbers (including fractions and integers) within said ranges.

“About” used herein refers to approximately, in the range of about or around. When used in combination with a value range, the term “about” modifies the range by extending the limit above or below the value provided. In general, the term “about” is used herein to give a value plus or minus 10% from the value provided. For instance, “about 50%” refers to a range of 45% to 55%. It should also be understood that all the integers and fractions are defined by the term “about”. Numerical values used herein include all numerical ranges that are the same as the numerical values after rounding to the nearest significant digit.

It should be understood that each member of the Markush group can be used to describe the present invention individually and/or in combination. “Or a combination thereof” used herein is “or any combination thereof”.

The stereochemistry of a chiral center used herein may be defined according to the convention of a person skilled in the art, i.e., using a wedged bond “ [symbol] ” to indicate a group pointing out of the plane of the paper (the side towards the observer) and using a hashed bond “ [symbol] ” to indicate a group pointing into the plane of the paper (the side away from the observer). It may be understood that such representations are used for indicating a specific single stereoisomer of groups represented by each chemical structure herein. Any bond that is not specifically represented by the wedged bond or the hashed bond herein shall be regarded as not specifically indicating whether the bond is in front of the plane of the paper, or behind the plane of the paper, or located in the plane of the paper. However, it does not exclude that the bond is in front of or behind the plane of the paper if chemically allowed. “Isomer” used herein refers to compounds that have the same molecular formula but differ in the nature or sequence of bonding of their atoms or the arrangement of their atoms in space. The term “stereoisomer” refers to isomers that differ in the arrangement of their atoms in space; the term “enantiomer” refers to stereoisomers with one or more asymmetric centers that are non-superimposable mirror images of one another; the term “diastereomer” refers to stereoisomers not belonging to enantiomers having opposite configurations at one or more asymmetric centers. If a compound has an asymmetric center, for instance, if a carbon atom is bonded to four different groups, a pair of enantiomers may exist. A configuration of an enantiomer may be characterized and designated as the R-configuration or the S-configuration by the absolute configuration of one or more asymmetric centers of the enantiomer, or the enantiomer is designated as dextrorotatory or levorotatory based on the manner in which the molecule rotates the plane of polarized light. A chiral compound may exist in the form of an enantiomer alone or a mixture of enantiomers, for instance, exist in the form of a racemic mixture. The compound of the present application may have an asymmetric center or chiral center, and exist in the form of different stereoisomers. It should be regarded that all stereoisomers of the compound of the present application include a diastereomer, an enantiomer, an atropisomer, and a mixture thereof, such as a racemic mixture, which form part of the present application, but the present invention is not limited thereto.

In the structural formulae herein, “*” represents a bonding site.

The “polymer” used herein refers to a product formed by the polymerization of a monomer. The polymer may include homopolymer, copolymer, prepolymer, or the like, but the present invention is not limited thereto.

The “homopolymer” used herein refers to a chemical substance formed by polymerization, addition polymerization, and condensation polymerization of a single compound. The “copolymer” refers to a chemical substance formed by polymerization, addition polymerization, or condensation polymerization of two or more compounds, including random copolymer (having a structure such as -AABABBBAAABBA-), alternating copolymer (having a structure such as -ABABABAB-), graft copolymer (having a structure such as -AA(A-BBBB)AA(A-BBBB)AAA-), block copolymer (having a structure such as -AAAAA-BBBBBB-AAAAA-), and the like. The copolymer of the present application should be regarded as it may refer to the polymer obtained by copolymerization using phenylvinylsilane and vinyl-containing compound A monomer; as long as the copolymer only has a copolymer of phenylvinylsilane and vinyl-containing compound A, and there is no particular limitation on whether units of a main chain backbone of the macromolecule and a side chain thereof have been modified or reformed.

The “prepolymer” used herein refers to a lower molecular weight polymer having a molecular weight between that of the monomer and the final polymer, and the prepolymer contains reactive functional groups that may be further polymerized to obtain a fully crosslinked or hardened higher molecular weight product.

The polymer includes oligomer, but the present invention is not limited thereto. The oligomer, a.k.a. low molecular polymer, consists of 2 to 20 repeating units, usually 2 to 5 repeating units.

The “modifier” used herein includes a product after modification of the reactive functional group of each resin, a product after prepolymerization of each resin with other resins, a product after crosslinking of each resin with other resins, a product after homopolymerization of each resin, a product after copolymerization of each resin with other resins, and the like. For instance, modification may be to replace the original hydroxyl into vinyl through a chemical reaction, or to obtain a hydroxyl-terminated through a chemical reaction between the original vinyl-terminated and aminophenol-terminated, but the present invention is not limited thereto.

Various alkyl, various alkenyl, and various hydrocarbyl used herein are meant to include the various isomers thereof. For instance, “propy” used herein includes n-propyl and isopropyl.

The “vinyl-containing” means that a compound structure contains an ethylenic carbon-carbon double bond (C═C) or a functional group derived therefrom. Thus, vinyl-containing examples may include that containing functional groups such as vinyl, allyl, vinylbenzyl, methacrylate, or the like, in the structure thereof, but the present invention is not limited thereto. The position of the functional group used herein may be at the terminal of a long chain structure, but the present invention is not limited thereto. Thus, for instance, a vinyl-containing polyphenylene ether resin represents a polyphenylene ether resin containing functional groups such as vinyl, allyl, vinylbenzyl, methacrylate, or the like, but the present invention is not limited thereto. Accordingly, the “vinyl-containing polyphenylene ether resin” used herein refers to a polyphenylene ether compound or mixture having the ethylenic carbon-carbon double bonds (C═C) or functional groups derived therefrom, and examples thereof may include polyphenylene ether resins containing vinyl, vinylidene, allyl, vinylbenzyl, or methacrylate, but the present invention is not limited thereto.

The “unsaturated bond” used herein refers to a reactive unsaturated bond, such as, but not limited to, an unsaturated double bond that may undergo a crosslinking reaction with other functional groups, such as an unsaturated carbon-carbon double bond that may undergo a crosslinking reaction with other functional groups, but the present invention is not limited thereto.

The “resin” used herein may generally be a customary designation for synthetic polymers. The “resin” used herein may include forms of a monomer, a polymer thereof, a combination of monomers, a combination of polymers thereof, or a combination of monomers and polymers thereof, or the like, but the present invention is not limited thereto. For instance, the “maleimide resin” used herein includes at least a maleimide monomer (a maleimide small molecule compound), a maleimide polymer, a combination of maleimide monomers, a combination of maleimide polymers, and a combination of the maleimide monomer and the maleimide polymer.

Parts by weight used herein represent represents a number of parts of weight, which may be any unit of weight, such as kilograms, grams, and pounds, but the present invention is not limited thereto. For instance, 100 parts by weight of the vinyl-containing polyphenylene ether resin may represent 100 kilograms of the vinyl-containing polyphenylene ether resin or 100 pounds of the vinyl-containing polyphenylene ether resin.

### Embodiments of the Present Application

In one aspect, the present application provides a copolymer.

In some exemplery examples, the copolymer comprises a structural unit formed from phenylvinylsilane and vinyl-containing compound A.

In some exemplery examples, raw materials of the copolymer comprise phenylvinylsilane and vinyl-containing compound A; based on a total weight of phenylvinylsilane and the vinyl-containing compound A being 100 parts by weight, phenylvinylsilane is 80 to 98 parts by weight, and the vinyl-containing compound A is 2 to 20 parts by weight.

In some exemplery examples, phenylvinylsilane is 80 to 98 parts by weight, and vinyl-containing compound A is 2 to 20 parts by weight; particularly, phenylvinylsilane is 85 to 98 parts by weight, and vinyl-containing compound A is 2 to 15 parts by weight; or, particularly, phenylvinylsilane is 80 to 95 parts by weight, and vinyl-containing compound A is 5 to 20 parts by weight. In some exemplery examples, phenylvinylsilane is 85 to 95 parts by weight, and vinyl-containing compound A is 5 to 15 parts by weight; particularly, phenylvinylsilane is 90 to 95 parts by weight, and vinyl-containing compound A is 5 to 10 parts by weight; or, particularly, phenylvinylsilane is 85 to 90 parts by weight, and vinyl-containing compound A is 10 to 15 parts by weight. In some exemplery examples, phenylvinylsilane is 80 parts by weight. In some exemplery examples, phenylvinylsilane is 85 parts by weight. In some exemplery examples, phenylvinylsilane is 90 parts by weight. In some exemplery examples, phenylvinylsilane is 95 parts by weight. In some exemplery examples, phenylvinylsilane is 98 parts by weight. In some exemplery examples, vinyl-containing compound A is 2 parts by weight. In some exemplery examples, vinyl-containing compound A is 5 parts by weight. In some exemplery examples, vinyl-containing compound A is 10 parts by weight. In some exemplery examples, vinyl-containing compound A is 15 parts by weight. In some exemplery examples, vinyl-containing compound A is 20 parts by weight. In some exemplery examples, phenylvinylsilane is 80 parts by weight, and vinyl-containing compound A is 20 parts by weight. In some exemplery examples, phenylvinylsilane is 85 parts by weight, and vinyl-containing compound A is 15 parts by weight. In some exemplery examples, phenylvinylsilane is 90 parts by weight, and vinyl-containing compound A is 10 parts by weight. In some exemplery examples, phenylvinylsilane is 95 parts by weight, and vinyl-containing compound A is 5 parts by weight. In some exemplery examples, phenylvinylsilane is 98 parts by weight, and vinyl-containing compound A is 2 parts by weight.

In some exemplery examples, the copolymer comprises 78 mol % to 99 mol % of structural units formed from phenylvinylsilane. In some exemplery examples, the copolymer comprises 84 mol % to 97 mol %, particularly 88 mol % to 97 mol %, or particularly 84 mol % to 94 mol % of structural units formed from phenylvinylsilane. In some exemplery examples, the copolymer comprises 88 mol % to 94 mol %, particularly 88 mol % to 92 mol %, or particularly 92 mol % to 94 mol % of structural units formed from phenylvinylsilane. In some exemplery examples, the copolymer comprises any one of 78 mol %, 79 mol %, 80 mol %, 81 mol %, 82 mol %, 83 mol %, 84 mol %, 85 mol %, 86 mol %, 87 mol %, 88 mol %, 89 mol %, 90 mol %, 91 mol %, 92 mol %, 93 mol %, 94 mol %, 95 mol %, 96 mol %, 97 mol %, 98 mol %, or 99 mol %, or any range with any two of them as endpoints, of structural units formed from phenylvinylsilane.

In some exemplery examples, the copolymer comprises 1 mol % to 22 mol % of structural units formed from vinyl-containing compound A. In some exemplery examples, the copolymer comprises 3 mol % to 16 mol %, particularly 3 mol % to 12 mol %, or particularly 6 mol % to 16 mol % of structural units formed from vinyl-containing compound A. In some exemplery examples, the copolymer comprises 6 mol % to 12 mol %, particularly 8 mol % to 12 mol %, or particularly 6 mol % to 8 mol % of structural units formed from vinyl-containing compound A. In some exemplery examples, the copolymer comprises any one of 1 mol %, 2 mol %, 3 mol %, 4 mol %, 5 mol %, 6 mol %, 7 mol %, 8 mol %, 9 mol %, 10 mol %, 11 mol %, 12 mol %, 13 mol %, 14 mol %, 15 mol %, 16 mol %, 17 mol %, 18 mol %, 19 mol %, 20 mol %, 21 mol %, or 22 mol %, or any range with any two of them as endpoints, of structural units formed from vinyl-containing compound A.

In some exemplery examples, the phenylvinylsilane has a structure of formula (1) or formula (2), and the vinyl-containing compound A has a structure of formula (3),

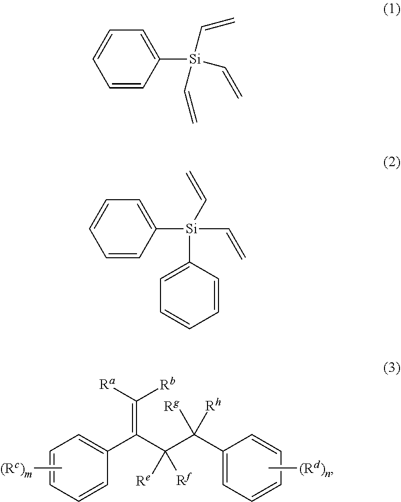

and
   wherein,
      R^{a}, R^{b}, R^{c}, and R^{d} are each independently H or a monovalent organic group;
      m and n are each independently an integer from 0 to 5; and
      R^{e}, R^{f}, R^{g}, and R^{h} are each independently H or monovalent alkyl having 1 to 4 carbon atoms.

In some exemplery examples, the monovalent organic group may be methyl, ethyl, propyl, butyl, tert-butyl, pentyl, hexyl, heptyl, octyl, nonyl, decyl, phenyl, benzyl, methoxy, ethoxy, propoxy, butoxy, phenoxy, or benzyloxy. In some exemplery examples, the monovalent organic group may be monovalent alkyl or alkoxy having 1 to 10 carbon atoms. In some exemplery examples, the monovalent organic group may be monovalent alkyl or alkoxy having 1 to 4 carbon atoms.

In some exemplery examples, monovalent alkyl having 1 to 4 carbon atoms may be methyl, ethyl, n-propyl, isopropyl, n-butyl, isobutyl, sec-butyl, or tert-butyl.

In some exemplery examples, R^{a} and R^{b} are each independently H or monovalent alkyl having 1 to 4 carbon atoms. In some exemplery examples, R^{a} and R^{b} are each independently H, methyl, ethyl, n-propyl, isopropyl, n-butyl, isobutyl, sec-butyl, or tert-butyl. In some exemplery examples, R^{a} and R^{b} are each independently H, methyl, or ethyl. In some exemplery examples, R^{a} and R^{b} are each independently H or methyl. In some exemplery examples, R^{a} is H. In some exemplery examples, R^{b} is H. In some exemplery examples, R^{a} and R^{b} are both H.

In some exemplery examples, R^{c} and R^{d} are each independently H or monovalent alkoxy having 1 to 4 carbon atoms. In some exemplery examples, monovalent alkoxy having 1 to 4 carbon atoms may be methoxy, ethoxy, n-propoxy, isopropoxy, n-butoxy, isobutoxy, sec-butoxy, or tert-butoxy. In some exemplery examples, R^{c} is H. In some exemplery examples, R^{d} is H. In some exemplery examples, R^{c} and R^{d} are both H. In some exemplery examples, R^{c} is monovalent alkoxy having 1 to 4 carbon atoms. In some exemplery examples, R^{d} is monovalent alkoxy having 1 to 4 carbon atoms. In some exemplery examples, RV and R^{d} are both monovalent alkoxy having 1 to 4 carbon atoms. In some exemplery examples, R^{c} is H or methoxy. In some exemplery examples, R^{d} is H or methoxy. In some exemplery examples, R^{c} and R^{d} are each independently H or methoxy. In some exemplery examples, R^{c} is methoxy. In some exemplery examples, R^{d} is methoxy. In some exemplery examples, R^{c} and R^{d} are both methoxy. In some exemplery examples, R^{c} is a para substituent. In some exemplery examples, R^{d} is a para substituent. In some exemplery examples, R^{c} and R^{d} are both para substituents. In some exemplery examples, R^{c} is para-substituted methoxy. In some exemplery examples, R^{d} is para-substituted methoxy. In some exemplery examples, R^{c} and R^{d} are both para-substituted methoxy.

In some exemplery examples, R^{e} and R^{f} are each independently H, methyl, ethyl, n-propyl, isopropyl, n-butyl, isobutyl, sec-butyl, or tert-butyl. In some exemplery examples, R^{e} and R^{f} are each independently H, methyl, or ethyl. In some exemplery examples, R^{e} and R^{f} are each independently H or methyl. In some exemplery examples, R^{e} is H or methyl. In some exemplery examples, R^{f} is H or methyl. In some exemplery examples, R^{e} is H. In some exemplery examples, R^{f} is H. In some exemplery examples, R^{e} is methyl. In some exemplery examples, R^{f} is methyl. In some exemplery examples, R^{e} and R^{f} are both H. In some exemplery examples, one of R^{e} and R^{f} is H and the other is methyl.

In some exemplery examples, R^{g} and R^{h} are each independently H, methyl, ethyl, n-propyl, isopropyl, n-butyl, isobutyl, sec-butyl, or tert-butyl. In some exemplery examples, R^{g} and R^{h} are each independently H, methyl, or ethyl. In some exemplery examples, R^{g} and R^{h} are each independently methyl or ethyl. In some exemplery examples, R^{g} is methyl or ethyl. In some exemplery examples, R^{h} is methyl or ethyl. In some exemplery examples, R^{g} is methyl. In some exemplery examples, R^{h} is methyl. In some exemplery examples, R^{g} is ethyl. In some exemplery examples, R^{h} is ethyl. In some exemplery examples, R^{g} and R^{h} are both methyl. In some exemplery examples, one of R^{g} and R^{h} is methyl and the other is ethyl.

In some exemplery examples, m is 0. In some exemplery examples, m is 1. In some exemplery examples, m is 2. In some exemplery examples, m is 3. In some exemplery examples, m is 4. In some exemplery examples, m is 5. In some exemplery examples, n is 0. In some exemplery examples, n is 1. In some exemplery examples, n is 2. In some exemplery examples, n is 3. In some exemplery examples, n is 4. In some exemplery examples, n is 5. In some exemplery examples, m and n are both 0. In some exemplery examples, m and n are both 1. In some exemplery examples, m and n are both 2. In some exemplery examples, m and n are both 3. In some exemplery examples, m and n are both 4. In some exemplery examples, m and n are both 5.

In some exemplery examples, the vinyl-containing compound A has a structure of formula (4), formula (5), or formula (6),

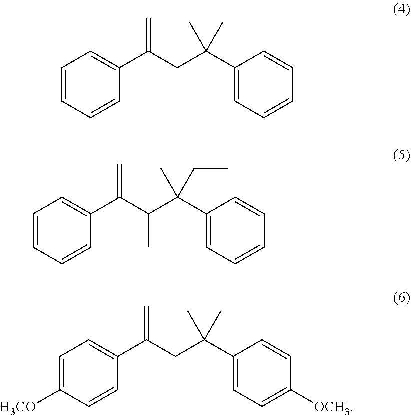

In some exemplery examples, the copolymer comprises J1 structures of formula (7), J2 structures of formula (8), J3 structures of formula (9), K1 structures of formula (10), K2 structures of formula (11), and L1 structures of formula (12),

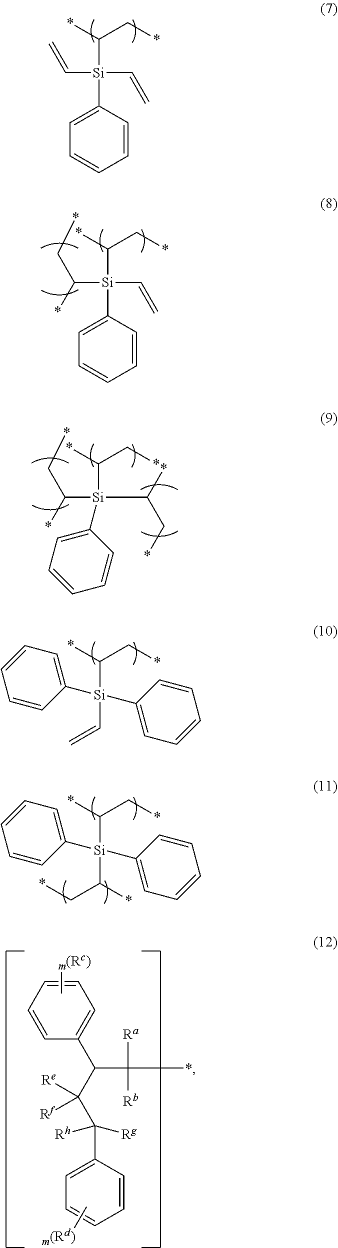

wherein,
   J1, J2, J3, K1, and K2 are each independently an integer greater than or equal to 0, but not simultaneously 0 (i.e., at least one of J1, J2, J3, K1, and K2 is not 0), and L1 is an integer greater than or equal to 1; and

$$10 \leq J 1 + J 2 + J 3 + L 1 \leq 268 ; or$$

$$8 \leq K 1 + K 2 + L 1 \leq 212 ; or$$

$$8 \leq J 1 + J 2 + J 3 + K 1 + K 2 + L 1 \leq 268.$$

In some exemplery examples, J1 and J2 are each independently an integer greater than or equal to 1, and J3, K1, and K2 are each independently an integer greater than or equal to 0. In some exemplery examples, J1, J2, and J3 are each independently an integer greater than or equal to 0, and K1 and K2 are each independently an integer greater than or equal to 1. In some exemplery examples, J1, J2, K1, and K2 are each independently an integer greater than or equal to 1, and J3 is an integer greater than or equal to 0.

In some exemplery examples, the copolymer comprises the structure of formula (7), the structure of formula (8), the structure of formula (9), and the structure of formula (12). In some exemplery examples, J1+J2+J3+L1=any one of 10, 20, 30, 40, 50, 60, 70, 80, 90, 100, 110, 120, 130, 140, 150, 160, 170, 180, 190, 200, 210, 220, 230, 240, 250, 260, or 268, or any range with any two of them as endpoints. In some exemplery examples, the copolymer comprises the structure of formula (10), the structure of formula (11), and the structure of formula (12). In some exemplery examples, K1+K2+L1=any one of 8, 10, 20, 30, 40, 50, 60, 70, 80, 90, 100, 110, 120, 130, 140, 150, 160, 170, 180, 190, 200, 210, or 212, or any range with any two of them as endpoints. In some exemplery examples, the copolymer comprises the structure of formula (7), the structure of formula (8), the structure of formula (9), the structure of formula (10), the structure of formula (11), and the structure of formula (12). In some exemplery examples, J1+J2+J3+K1+K2+L1=any one of 8, 10, 20, 30, 40, 50, 60, 70, 80, 90, 100, 110, 120, 130, 140, 150, 160, 170, 180, 190, 200, 210, 220, 230, 240, 250, 260, or 268, or any range with any two of them as endpoints.

In some exemplery examples, a weight average molecular weight of the copolymer is between 2,000 and 50,000. In some exemplery examples, the weight average molecular weight of the copolymer is any one of 2,000, 5,000, 10,000, 15,000, 20,000, 25,000, 30,000, 35,000, 40,000, 45,000, or 50,000, or any range with any two of them as endpoints. In an embodiment, the weight average molecular weight of the copolymer is 32,071. In an embodiment, the weight average molecular weight of the copolymer is 3,686.

In one aspect, the present application provides a method of preparing the copolymer.

In some exemplery examples, the method of preparing the copolymer comprises: reacting 80 to 98 parts by weight of phenylvinylsilane and 2 to 20 parts by weight of vinyl-containing compound A. In some exemplery examples, the reaction is conducted at 80° C. to 150° C. for 2 hours to 10 hours. In some exemplery examples, the method of preparing the copolymer further comprises the steps of purifying (i.e., refining, a.k.a. improving the purity thereof), filtering, or drying.

In some exemplery examples, a reaction time of the reaction may be between 2 hours and 10 hours, such as between 3 hours and 9 hours, between 4 hours and 8 hours, or between 5 hours and 7 hours.

In some exemplery examples, a reaction temperature of the reaction may be between 80° C. and 150° C., such as between 90° C. and 140° C., between 100° C. and 130° C., or between 110° C. and 120° C.

In some exemplery examples, the reaction is conducted in a presence of a curing accelerator, and the curing accelerator comprises an initiator, a catalyst, or a combination thereof. In some exemplery examples, the initiator is bis(tert-butylperoxyisopropyl)benzene, 2,5-dimethyl-2,5-di(tert-butylperoxy)-3-hexyne, dibenzoyl peroxide (BPO), 2,3-dimethyl-2,3-diphenylbutane, dicumyl peroxide, tert-butyl peroxybenzoate, tert-butyl peroxyisopropyl monocarbonate, azobisisobutylonitrile, or a combination thereof. In some exemplery examples, the catalyst is metal carboxylate.

In some exemplery examples, an amount of the initiator, catalyst, or combination thereof may be between 0.1% and 1.5% of a sum of an amount (such as parts by weight) of phenylvinylsilane and an amount of vinyl-containing compound A, such as between 0.2% and 1.4%, between 0.3% and 1.3%, between 0.4% and 1.2%, between 0.5% and 1.1%, between 0.6% and 1.0%, or between 0.7% and 0.9%.

In some exemplery examples, the reaction is conducted in a presence of a solvent. In some exemplery examples, the solvent is methanol, ethanol, ethylene glycol monomethyl ether, acetone, butanone (a.k.a. methyl ethyl ketone), methyl isobutyl ketone, cyclohexanone, toluene, xylene, methoxyethyl acetate, ethoxyethyl acetate, propoxyethyl acetate, ethyl acetate, dimethyl formamide, dimethyl acetamide, propylene glycol methyl ether, or a combination thereof.

In some exemplery examples, an amount of the solvent may be between 0% and 100% of the sum of the amount (such as parts by weight) of phenylvinylsilane and the amount of vinyl-containing compound A, such as between 10% and 90%, between 20% and 80%, between 30% and 70%, or between 40% and 60%.

In one aspect, the present application provides a resin composition. In one aspect, the present application provides a method of preparing the resin composition.

In some exemplery examples, the resin composition comprises the copolymer, a vinyl-containing polyphenylene ether resin, and a polyolefin resin.

In some exemplery examples, the method of preparing the resin composition comprises mixing the copolymer, the vinyl-containing polyphenylene ether resin, and the polyolefin resin.

In some exemplery examples, the resin composition comprises:
100 parts by weight of the copolymer;
15 to 70 parts by weight of a vinyl-containing polyphenylene ether resin; and
30 to 100 parts by weight of a polyolefin resin.

In some exemplery examples, the vinyl-containing polyphenylene ether resin comprises a vinylbenzyl-terminated polyphenylene ether resin, a methacrylate-terminated polyphenylene ether resin (i.e., a methacryloyl-terminated polyphenylene ether resin), a allyl-terminated polyphenylene ether resin, or a combination thereof. In some exemplery examples, the vinyl-containing polyphenylene ether resin comprises the vinylbenzyl-terminated polyphenylene ether resin. In some exemplery examples, the vinyl-containing polyphenylene ether resin comprises the methacrylate-terminated polyphenylene ether resin. In some exemplery examples, the vinyl-containing polyphenylene ether resin comprises the terminal allyl polyphenylene ether resin.

In some exemplery examples, the vinylbenzyl-terminated polyphenylene ether resin comprises a structure of formula (13),

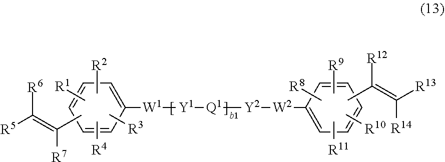

wherein,
   R¹ to R¹⁴ are each independently H or —CH₃;
   W¹ and W² are each independently a C₁ to C₃ divalent aliphatic group;
   b1 is an integer from 0 to 8;
   Q¹ comprises any one of structures of formula (B-1) to formula (B-3), or a combination thereof,

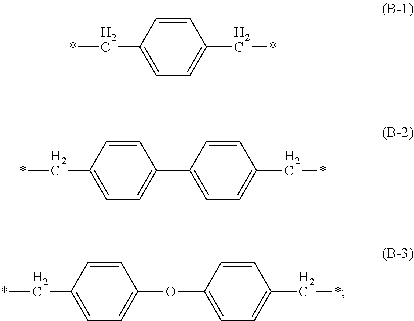

and
Y¹ and Y² each independently comprise a structure of formula (B-4),

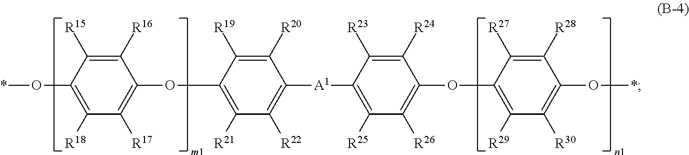

and
wherein,
   R¹⁵ to R³⁰ are each independently H or —CH₃;
   m1 and n1 are each independently an integer from 1 to 30; and
   A¹ is a covalent bond, —CH₂—, —CH(CH₃)—, —C(CH₃)₂—, —O—, —S—, —SO₂—, or carbonyl.

In some exemplery examples, the methacrylate-terminated polyphenylene ether resin comprises a structure of formula (14),

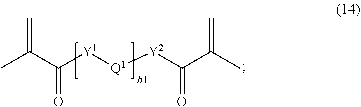

wherein,
   b1 is an integer from 0 to 8;
   Q¹ comprises any one of structures of formula (B-1) to formula (B-3), or a combination thereof, and

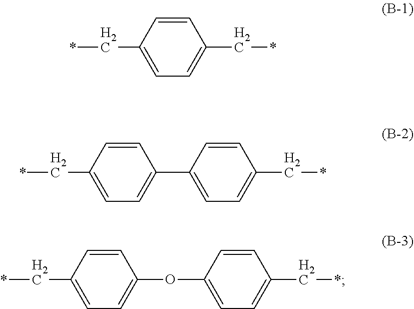

and
Y¹ and Y² each independently comprise a structure of formula (B-4),

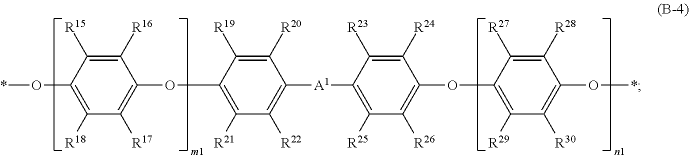

and
wherein,
   R¹⁵ to R³⁰ are each independently H or —CH₃;
   m1 and n1 are each independently an integer from 1 to 30; and
   A¹ is a covalent bond, —CH₂—, —CH(CH₃)—, —C(CH₃)₂—, —O—, —S—, —SO₂—, or carbonyl.

In some exemplery examples, the vinyl-containing polyphenylene ether resin may be amethacrylate-terminated polyphenylene ether resin (such as SA9000, available from Sabic), a vinylbenzyl-terminated polyphenylene ether resin having a number average molecular weight of about 1,200 (such as OPE-2st 1200, available from Mitsubishi Gas Chemical Company), a vinylbenzyl-terminated polyphenylene ether resin having a number average molecular weight of about 2,200 (such as OPE-2st 2200, available from Mitsubishi Gas Chemical Company), a vinylbenzyl-terminated modified bisphenol-A polyphenylene ether resin having a number average molecular weight of about 2,400 to 2,800, a vinyl-terminated chain extended polyphenylene ether resin having a number average molecular weight of about 2,200 to 3,000, or a combination thereof.

In some exemplery examples, the vinyl-terminated chain extended polyphenylene ether resin may comprise various types of polyphenylene ether resins disclosed in US 2016/0185904 A¹, the contents of which are incorporated herein by reference in their entirety.

In some exemplery examples, the resin composition comprises 15 to 70 parts by weight of the vinyl-containing polyphenylene ether resin compared to 100 parts by weight of the copolymer. In some exemplery examples, the resin composition comprises any one of 20, 25, 30, 35, 40, 45, 50, 55, 60, or 65 parts by weight, or any range with any two of them as endpoints, of the vinyl-containing polyphenylene ether resin.

In some exemplery examples, the polyolefin resin comprises an unsaturated polyolefin resin, a hydrogenated unsaturated polyolefin resin, or a combination thereof, but the present invention is not limited thereto. In some exemplery examples, the polyolefin resin comprises the unsaturated polyolefin resin. In some exemplery examples, the polyolefin resin comprises the hydrogenated unsaturated polyolefin resin.

In some exemplery examples, the unsaturated polyolefin resin may be any one or more polyolefin resins containing unsaturated carbon-carbon double bonds for the manufacture of prepreg, resin film, laminate, printed circuit board, or cured insulator. In some exemplery examples, the unsaturated polyolefin resin comprises at least one of styrene-butadiene-divinylbenzene terpolymer, maleic anhydride-added styrene-butadiene copolymer, maleic anhydride-added polybutadiene, styrene-butadiene-styrene block polymer, vinyl-polybutadiene-urethane oligomer, styrene-butadiene copolymer, styrene-isoprene copolymer, polybutadiene, ethylene propylene diene monomer, methylstyrene homopolymer, petroleum resin, or cyclic olefin copolymer, or a combination thereof, but the present invention is not limited thereto.

In some exemplery examples, the hydrogenated unsaturated polyolefin resin is obtained by hydrogenating the unsaturated polyolefin resin. In some exemplery examples, the hydrogenated unsaturated polyolefin resin may be any one or more of hydrogenated unsaturated polyolefin resins free of unsaturated carbon-carbon double bonds for the manufacture of prepreg, resin film, laminate, printed circuit board, or cured insulator. In some exemplery examples, the hydrogenated unsaturated polyolefin resin comprises at least one of hydrogenated styrene-butadiene copolymer, hydrogenated styrene-butadiene-styrene block polymer, or hydrogenated styrene-isoprene copolymer, or a combination thereof, but the present invention is not limited thereto.

In some exemplery examples, the resin composition comprises 30 to 100 parts by weight of the polyolefin resin compared to 100 parts by weight of the copolymer. In some exemplery examples, the resin composition comprises any one of 30, 40, 50, 60, 70, 80, or 90 parts by weight, or any range with any two of them as endpoints, of the polyolefin resin.

In some exemplery examples, the resin composition may also optionally comprise a maleimide resin, a maleimide triazine resin, a small molecule vinyl-containing resin, a small molecule vinyl-containing resin prepolymer, a styrene maleic anhydride resin, an epoxy resin, a phenol resin, a benzoxazine resin, a cyanate ester resin, a polyester resin, a polyamide resin, a polyimide resin, or a combination thereof. In some exemplery examples, the method of preparing the resin composition further comprises mixing the maleimide resin, the maleimide triazine resin, the small molecule vinyl-containing resin, the small molecule vinyl-containing resin prepolymer, the styrene maleic anhydride resin, the epoxy resin, the phenol resin, the benzoxazine resin, the cyanate ester resin, the polyester resin, the polyamide resin, the polyimide resin, or the combination thereof, with the copolymer, the vinyl-containing polyphenylene ether resin, and the polyolefin resin. Unless otherwise specified, the present application does not specifically limit an amount ratio between the copolymer and a resin additive.

In some exemplery examples, the resin composition comprises a maleimide resin. In some exemplery examples, the maleimide resin comprises a compound or mixture having more than one maleimide functional group in the molecule, such as a prepolymer having more than one maleimide functional group in the molecule. In some exemplery examples, the maleimide resin may be any one or more compounds or mixtures having more than one maleimide functional group in the molecule for the manufacture of prepreg, resin film, laminate, printed circuit board, or cured insulator. In some exemplery examples, the maleimide resin comprises 4,4′-diphenylmethane bismaleimide, phenylmethane maleimide oligomer, m-phenylene bismaleimide, bisphenol-A diphenyl ether bismaleimide, 3,3′-dimethyl-5,5′-diethyl-4,4′-diphenylmethane bismaleimide, 4-methyl-1,3-phenylene bismaleimide, 1,6-bismaleimide-(2,2,4-trimethyl) hexane, 2,3-dimethylbenzene maleimide, 2,6-dimethylbenzene maleimide, N-phenylmaleimide, maleimide resin containing an aliphatic long chain structure, or a combination thereof, but the present invention is not limited thereto. In some exemplery examples, the maleimide resin may be any one or more maleimide resin prepolymers having more than one maleimide functional group in the molecule for the manufacture of prepreg, resin film, laminate, printed circuit board, or cured insulator. In some exemplery examples, the maleimide resin comprises a prepolymer of a diallyl compound and the maleimide resin, a prepolymer of a multifunctional amine (comprising two or more amino groups) and the maleimide resin, a prepolymer of an acidic phenol compound and the maleimide resin, or a combination thereof, but the present invention is not limited thereto.

In some exemplery examples, the maleimide resin may be a maleimide resin produced by Daiwakasei under trade names of BMI-1000, BMI-1000H, BMI-1100, BMI-1100H, BMI-2000, BMI-2300, BMI-3000, BMI-3000H, BMI-4000H, BMI-5000, BMI-5100, BMI-7000, BMI-7000H, etc. or a maleimide resin produced by K. I. Chemical Company under trade names of BMI-70, BMI-80, etc. In some exemplery examples, the maleimide resin containing an aliphatic long chain structure may be a maleimide resin produced by Designer Molecular Company under trade names of BMI-689, BMI-1400, BMI-1500, BMI-1700, BMI-2500, BMI-3000, BMI-5000, BMI-6000, etc. For instance, the maleimide resin containing an aliphatic long chain structure may have at least one maleimide functional group attached to a substituted or unsubstituted long chain aliphatic group. The long chain aliphatic group may be an aliphatic group having a carbon number of C₅ to C₅₀, such as, but the present invention is not limited to, C₁₀ to C₅₀, C₂₀ to C₅₀, C₃₀ to C₅₀, C₂₀ to C₄₀, or C₃₀ to C₄₀.

In some exemplery examples, the resin composition comprises a maleimide triazine resin. In some exemplery examples, the maleimide triazine resin may be any one or more of maleimide triazine resins for the manufacture of prepreg, resin film, laminate, printed circuit board, or cured insulator. In some exemplery examples, the maleimide triazine resin may be obtained from the polymerization of the cyanate ester resin and the maleimide resin. In some exemplery examples, the maleimide triazine resin may be obtained from the polymerization of a bisphenol-A cyanate ester resin and the maleimide resin, from the polymerization of a bisphenol-F cyanate ester resin and the maleimide resin, from the polymerization of a phenol novolac cyanate ester resin and the maleimide resin, or from the polymerization of a dicyclopentadiene-containing cyanate ester resin and the maleimide resin. In some exemplery examples, the maleimide triazine resin may be obtained from the polymerization of any molar ratio of cyanate ester resin and the maleimide resin. In some exemplery examples, the maleimide triazine resin may be obtained from the polymerization of a molar ratio of (1-10):1, particularly (1-6):1, 1:1, 2:1, 4:1, or 6:1 of cyanate ester resin and the maleimide resin.

In some exemplery examples, the resin composition comprises a small molecule vinyl-containing resin. In some exemplery examples, the small molecule vinyl-containing resin may comprise a vinyl compound having a molecular weight less than or equal to 1000, particularly a molecular weight between 100 and 900, and more preferably a molecular weight between 100 and 800. In some exemplery examples, the small molecule vinyl-containing resin may comprise styrene, divinylbenzene, bis(vinylbenzyl) ether, 1,2,4-trivinylcyclohexane (TVCH), bis(vinylphenyl) ethane (BVPE), bis(vinylphenyl) hexane, divinylphenyl dimethylene ether, divinylphenyl dimethylene benzene, triallyl isocyanurate (TAIC), triallyl cyanurate (TAC), or a combination thereof, but the present invention is not limited thereto.

In some exemplery examples, the resin composition comprises a small molecule vinyl-containing resin prepolymer, and the small molecule vinyl-containing resin prepolymer may comprise a styrene prepolymer, a divinylbenzene prepolymer, a bis(vinylbenzyl) ether prepolymer, a TVCH prepolymer, a BVPE prepolymer, a bis(vinylphenyl) hexane prepolymer, a divinylphenyl dimethylene ether prepolymer, a divinylphenyl dimethylene benzene prepolymer, a TAIC prepolymer, a TAC prepolymer, or a combination thereof, but the present invention is not limited thereto. For instance, in some exemplery examples, the styrene prepolymer represents a styrene content in the prepolymer of greater than or equal to 50 wt %, such as a styrene content in the styrene prepolymer of between 50 wt % and 99 wt %, and a second monomer unit content in the styrene prepolymer of less than or equal to 49 wt %, such as between 1 wt % and 49 wt %. For instance, in an embodiment, the styrene prepolymer comprises 60 wt % styrene monomer units, 30 wt % divinylbenzene monomer units, and 10 wt % ethylstyrene monomer units. In another embodiment, the divinylbenzene prepolymer comprises 60 wt % divinylbenzene monomer units, 30 wt % ethylstyrene monomer units, and 10 wt % styrene monomer units.

In some exemplery examples, the resin composition comprises styrene maleic anhydride resin. In some exemplery examples, a molar ratio of styrene and maleic anhydride in the styrene maleic anhydride resin may be (1-8):1, such as 1:1, 2:1, 3:1, 4:1, 6:1, or 8:1. In some exemplery examples, the styrene maleic anhydride resin may be a styrene maleic anhydride copolymer. In some exemplery examples, the styrene maleic anhydride copolymer may be a styrene maleic anhydride copolymer available from Cray Valley under trade names of SMA-1000, SMA-2000, SMA-3000, EF-30, EF-40, EF-60, EF-80, etc., or a styrene maleic anhydride copolymer sold by Polyscope under trade names of C400, C500, C700, C900, etc. but the present invention is not limited thereto. In some exemplery examples, the styrene maleic anhydride resin is an esterified styrene maleic anhydride copolymer. In some exemplery examples, the esterified styrene maleic anhydride copolymer may be an esterified styrene maleic anhydride copolymer available from Cray Valley under trade names SMA1440, SMA17352, SMA2625, SMA3840, SMA31890, etc. but the present invention is not limited thereto. In some exemplery examples, the resin composition comprises one styrene maleic anhydride resin. In some exemplery examples, the resin composition comprises a combination of a plurality of styrene maleic anhydride resins.

In some exemplery examples, the resin composition comprises an epoxy resin. The epoxy resins may be of various types known in the art. In some exemplery examples, the epoxy resin may comprise a bisphenol-A epoxy resin, a bisphenol-F epoxy resin, a bisphenol-S epoxy resin, a bisphenol-AD epoxy resin, a novolac epoxy resin, a trifunctional epoxy resin, a tetrafunctional epoxy resin, a multifunctional novolac epoxy resin, a dicyclopentadiene (DCPD) epoxy resin, a phosphorus-containing epoxy resin, a p-xylene epoxy resin, a naphthalene epoxy resin (such as a naphthol epoxy resin), a benzofuran type epoxy resin, an isocyanate-modified epoxy resin, or a combination thereof, but the present invention is not limited thereto. In some exemplery examples, the novolac epoxy resin may comprise a phenol novolac epoxy resin, a bisphenol A novolac epoxy resin, a bisphenol F novolac epoxy resin, a biphenyl novolac epoxy resin, a phenol benzaldehyde epoxy resin, a phenol aralkyl novolac epoxy resin, an o-cresol novolac epoxy resin, or a combination thereof, but the present invention is not limited thereto. In some exemplery examples, the phosphorus-containing epoxy resin may be a 9,10-dihydro-9-oxa-10-phosphaphenanthrene-10-oxide (DOPO) epoxy resin, a DOPO-HQ epoxy resin, or a combination thereof, but the present invention is not limited thereto. In some exemplery examples, the DOPO epoxy resin may comprise a DOPO-containing phenolic novolac epoxy resin, a DOPO-containing cresol novolac epoxy resin, a DOPO-containing bisphenol-A novolac epoxy resin, or a combination thereof, but the present invention is not limited thereto. In some exemplery examples, the DOPO-HQ epoxy resin may comprise a DOPO-HQ-containing phenolic novolac epoxy resin, a DOPO-HQ-containing cresol novolac epoxy resin, a DOPO-HQ-containing bisphenol-A novolac epoxy resin, or a combination thereof, but the present invention is not limited thereto.

In some exemplery examples, the resin composition comprises a phenol resin. In some exemplery examples, the phenol resin may be a monofunctional phenol resin, a multifunctional phenol (comprising greater than or equal to two phenolic hydroxyl groups) resin, or a combination thereof, but the present invention is not limited thereto. In some exemplery examples, the phenol resin may comprise a phenoxy resin, a phenolic resin, or a combination thereof, but the present invention is not limited thereto.

In some exemplery examples, the resin composition comprises a benzoxazine resin. In some exemplery examples, the benzoxazine resin may comprise a bisphenol-A type benzoxazine resin, a bisphenol-F type benzoxazine resin, a phenolphthalein type benzoxazine resin, a dicyclopentadiene benzoxazine resin, a phosphorus-containing benzoxazine resin, or a combination thereof, but the present invention is not limited thereto. In some exemplery examples, the benzoxazine resin is, for instance, produced by Huntsman under a trade name LZ-8270 (phenolphthalein type benzoxazine resin), LZ-8280 (bisphenol-F type benzoxazine resin), LZ-8290 (bisphenol-A type benzoxazine resin), or by Showa Polymer Company under a trade name HFB-2006M.

In some exemplery examples, the resin composition comprises a cyanate ester resin. The cyanate ester resins may be of various types known in the art. In some exemplery examples, the cyanate ester resin may comprise a cyanate ester resin having an Ar—O—C≡N structure (where Ar is an aromatic group, such as benzene, naphthalene, or anthracene), but the present invention is not limited thereto. In some exemplery examples, the cyanate ester resin may comprise a phenolic novolac type cyanate ester resin, a bisphenol-A type cyanate ester resin, a bisphenol-A novolac type cyanate ester resin, a bisphenol-F type cyanate ester resin, a bisphenol-F novolac type cyanate ester resin, a cyanate ester resin containing a dicyclopentadiene structure, a cyanate ester resin containing a naphthalene ring structure, a phenolphthalein type cyanate ester resin, or a combination thereof, but the present invention is not limited thereto. In some exemplery examples, the cyanate ester resin may comprise a cyanate ester resin produced by Lonza under trade names of Primaset PT-15, PT-30S, PT-60S, BA-200, BA-230S, BA-3000S, BTP-2500, BTP-6020S, DT-4000, DT-7000, ULL 950S, HTL-300, CE-320, LVT-50, LeCy, etc. or a combination thereof, but the present invention is not limited thereto.

In some exemplery examples, the resin composition comprises a polyester resin. In some exemplery examples, the polyester resin is esterified with an aromatic compound having a dicarboxylic acid group and an aromatic compound having a dihydroxy group. In some exemplery examples, the polyester resin may be HPC-8000, HPC-8150, and HPC-8200 available from DIC, or a combination thereof, but the present invention is not limited thereto.

In some exemplery examples, the resin composition comprises a polyamide resin. The polyamide resins may be of various types known in the art and comprises various commercially available polyamide resin products, but the present invention is not limited thereto.

In some exemplery examples, the resin composition comprises a polyimide resin. The polyimide resins may be of various types known in the art and comprises various commercially available polyimide resin products, but the present invention is not limited thereto.

In some exemplery examples, in addition to the above-mentioned copolymer and any one or more of resin additives, the resin composition may also optionally comprise an amine curing agent, a flame retardant, an inorganic filler, a curing accelerator, a polymerization inhibitor, a colorant, a solvent, a toughening agent, a silane coupling agent, or a combination thereof. In some exemplery examples, the resin composition comprises the copolymer, the vinyl-containing polyphenylene ether resin, and the polyolefin resin, and further comprises the amine curing agent, the flame retardant, the inorganic filler, the curing accelerator, the polymerization inhibitor, the colorant, the solvent, the toughening agent, the silane coupling agent, or a combination thereof.

In some exemplery examples, the resin composition comprises an amine curing agent. In some exemplery examples, the amine curing agent may comprise dicyandiamide, diaminodiphenyl sulfone, diaminodiphenyl methane, diaminodiphenyl ether, diaminodiphenyl sulfide, or a combination thereof, but the present invention is not limited thereto.

In some exemplery examples, the resin composition comprises a flame retardant. In some exemplery examples, the flame retardant may be any one or more of flame retardants for the manufacture of prepreg, resin film, laminate, printed circuit board, or cured insulator.

In some exemplery examples, the flame retardant may be a phosphorus-containing flame retardant. In some exemplery examples, the flame retardant may be ammonium polyphosphate, hydroquinone bis-(diphenylphosphate), bisphenol A bis-(diphenylphosphate), tri (2-carboxyethyl) phosphine (TCEP), tris(chloroisopropyl) phosphate, trimethyl phosphate (TMP), dimethyl methyl phosphonate (DMMP), resorcinol bis(dixylenyl phosphate) (RDXP, commercially available products such as PX-200, PX-201, and PX-202), phosphazene compounds (commercially available products such as SPB-100, SPH-100, and SPV-100), melamine polyphosphate, DOPO and derivatives or resins thereof, diphenylphosphine oxide (DPPO) and derivatives or resins thereof, melamine cyanurate, tri-hydroxy ethyl isocyanurate, aluminum hypophosphite (products such as OP-930 and OP-935), or a combination thereof, but the present invention is not limited thereto.

In some exemplery examples, the flame retardant may be a DPPO compound (such as a bis-DPPO compound), a DOPO compound (such as a bis-DOPO compound), a DOPO resin (such as DOPO-HQ, DOPO-NQ, DOPO-PN, and DOPO-BPN), a DOPO-bonded epoxy resin, or a combination thereof, but the present invention is not limited thereto. The DOPO-PN is a DOPO phenolic novolac compound and the DOPO-BPN may be a bisphenol novolac compound such as DOPO-bisphenol A novolac (DOPO-BPAN), DOPO-bisphenol F novolac (DOPO-BPFN), DOPO-bisphenol S novolac (DOPO-BPSN), or the like.

In some exemplery examples, the resin composition comprises an inorganic filler. In some exemplery examples, the inorganic filler may be any one or more of fillers for the manufacture of prepreg, resin film, laminate, printed circuit board, or cured insulator. In some exemplery examples, the inorganic filler may be silica (molten, non-molten, porous, or hollow), alumina, aluminum hydroxide, magnesium oxide, magnesium hydroxide, calcium carbonate, aluminum nitride, boron nitride, aluminum silicon carbide, silicon carbide, titanium dioxide, zinc oxide, zirconium oxide, mica, boehmite (AlOOH), calcined talc, talc, silicon nitride, calcined kaolin, or a combination thereof, but the present invention is not limited thereto. In some exemplery examples, the inorganic filler may be in the form of spheres, fibers, plates, granules, flakes, or whiskers, and optionally pre-treated with the silane coupling agent.

In some exemplery examples, the resin composition comprises a curing accelerator. In some exemplery examples, the curing accelerator may comprise catalysts, such as Lewis bases and Lewis acids. In some exemplery examples, the Lewis base may comprise imidazole, boron trifluoride amine complex, ethyltriphenyl phosphonium chloride, 2-methylimidazole (2 MI), 2-phenyl-1H-imidazole (2PZ), 2-ethyl-4-methylimidazole (2E4MI), triphenylphosphine (TPP), 4-dimethylaminopyridine (DMAP), or a combination thereof, but the present invention is not limited thereto. In some exemplery examples, the Lewis acid may comprise metal salt compounds, such as manganese salt, iron salt, cobalt salt, nickel salt, copper salt, and zinc salt, particularly metal catalysts such as zinc octoate, cobalt octoate, or the like. In some exemplery examples, the curing accelerator comprises a curing initiator. In some exemplery examples, the curing initiator comprises a peroxide that may generate radicals. In some exemplery examples, the curing initiator comprises 2,3-dimethyl-2,3-diphenylbutane, dicumyl peroxide, tert-butyl peroxybenzoate, tert-butyl peroxyisopropyl monocarbonate, dibenzoyl peroxide (BPO), 2,5-dimethyl-2,5-di(tert-butylperoxy)-3-hexyne (25B), bis(tert-butylperoxyisopropyl) benzene, azobisisobutylonitrile, or a combination thereof, but the present invention is not limited thereto.

In some exemplery examples, the resin composition comprises a polymerization inhibitor. The polymerization inhibitor may be of various types known in the art and comprises various commercially available polymerization inhibitor products, but is not limited thereto. In some exemplery examples, the polymerization inhibitor may comprise 1,1-diphenyl-2-trinitrophenylhydrazine, methacrylonitrile, dithioester, a nitroxide stable radical, a triphenylmethyl radical, a metal ion radical, a sulfur radical, hydroquinone, p-methoxyphenol, p-benzoquinone, phenothiazine, β-phenylnaphthylamine, p-tert-butylcatechol, methylene blue, 4,4′-butylidene bis(6-tert-butyl-3-methylphenol), 2,2′-methylene bis(4-ethyl-6-tert-butylphenol), or a combination thereof, but the present invention is not limited thereto.

In some exemplery examples, the polymerization inhibitor comprises or consists of the nitroxide stable radical. In some exemplery examples, the nitroxide stable radical may comprise a 2,2,6,6-tetrasubstituent piperidine 1-oxyl, a 2,2,5,5-tetrasubstituent pyrrolidine 1-oxyl, or the like nitroxide radical from cyclic hydroxylamine, or a combination thereof, but the present invention is not limited thereto. The “substituent” herein is, for instance, an alkyl group with a carbon number of less than 4, such as methyl, ethyl, propyl, or butyl, particularly methyl or ethyl. In some exemplery examples, the nitroxide stable radical may be 2,2,6,6-tetramethylpiperidin 1-oxyl, 2,2,6,6-tetraethylpiperidin 1-oxyl, 2,2,6,6-tetramethyl-4-oxopiperidin 1-oxyl, 2,2,5,5-tetramethylpyrrolidin 1-oxyl, 1,1,3,3-tetramethylisoindoline 2-oxyl, N,N-di-tert-butylamine oxyl, or a combination thereof, but the present invention is not limited thereto. Stable radicals such as galvinoxyl radicals may also be used in place of nitroxide radicals.

In some exemplery examples, the polymerization inhibitor may also be a product derived from the substitution of hydrogen atoms or atomic groups in the aforementioned polymerization inhibitor by other atoms or atomic groups, such as products derived from the substitution of hydrogen atoms in the polymerization inhibitor by atomic groups such as amino groups, hydroxyl groups, and ketone carbonyl groups.

In some exemplery examples, the resin composition comprises a colorant. In some exemplery examples, the colorant may comprise a dye or a pigment, but the present invention is not limited thereto.

In some exemplery examples, the resin composition comprises a solvent. In some exemplery examples, the addition of the solvent may change a solid content of the resin composition and may adjust the viscosity of the resin composition. In some exemplery examples, the solvent may comprise methanol, ethanol, ethylene glycol monomethyl ether, acetone, butanone (a.k.a. methyl ethyl ketone), methyl isobutyl ketone, cyclohexanone, toluene, xylene, methoxyethyl acetate, ethoxyethyl acetate, propoxyethyl acetate, ethyl acetate, dimethyl formamide, dimethyl acetamide, propylene glycol methyl ether, or a combination thereof, but the present invention is not limited thereto. In some exemplery examples, the solvent added into the resin composition may be removed by volatilization during treatment of the resin composition into the prepreg or resin film. Therefore, an insulating layer of the prepreg or resin film contains no solvent or only a minor amount of solvent of less than or equal to 3 wt % (i.e., 3% by weight); thus, the presence or absence of solvent in the resin composition does not affect the characteristics of the product.

In some exemplery examples, the resin composition comprises a toughening agent. In some exemplery examples, the toughening agent may improve the toughness of the resin composition. In some exemplery examples, the toughening agent may comprise carboxyl-terminated butadiene acrylonitrile rubber (CTBN), core-shell rubber, or a combination thereof, but the present invention is not limited thereto.

In some exemplery examples, the resin composition comprises a silane coupling agent. In some exemplery examples, the silane coupling agent may comprise silane. The silane comprises siloxane, but the present invention is not limited thereto. In some exemplery examples, the silane coupling agent may comprise amino silane, eepoxide silane, vinyl silane, acrylate silane, methacrylate silane, hydroxyl silane, isocyanate silane, methacryloxy silane, acryloxy silane, or a combination thereof, but the present invention is not limited thereto.

In one aspect, the present application provides at least a portion of the product made from the resin composition. In some exemplery examples, the product is used for a component in various types of electronic products. In one aspect, the present application provides a use of the copolymer of the present application or the resin composition of the present application in preparing a product. In some exemplery examples, the present application provides a use of the copolymer of the present application or the resin composition of the present application in preparing the prepreg, the resin film, the laminate, the printed circuit board, or the cured insulator. In one aspect, the present application provides a product, comprising a resin layer made from the resin composition. In one aspect, the present application provides a method of preparing the product, comprising providing the resin layer made from the resin composition. In some exemplery examples, the product is a prepreg, a resin film, a laminate, a printed circuit board, or a cured insulator, but the present invention is not limited thereto.

In some exemplery examples, the product comprises the resin composition in a semi-cured (B-stage) or cured state (C-stage). In some exemplery examples, the product comprises the resin layer, wherein the resin layer is the resin composition in the semi-cured or cured state. In some exemplery examples, the product comprises the insulating layer, wherein the insulating later is the resin composition in the cured state.

In some exemplery examples, the present application provides a prepreg. In one aspect, the present application provides the use of the copolymer of the present application or the resin composition of the present application in preparing the prepreg. In some exemplery examples, the prepreg comprises a reinforcing material and a semi-cured layer provided on the reinforcing material, where the semi-cured layer is the resin composition in the semi-cured state. In some exemplery examples, the semi-cured layer is obtained by heating the resin composition to form the semi-cured state. In some exemplery examples, a method of preparing the prepreg is provided, comprising: providing the resin composition on the reinforcing material, and semi-curing the resin composition, particularly heating the resin composition to form the prepreg comprising the reinforcing material and the semi-cured layer. In some exemplery examples, the resin composition is provided on the reinforcing material, comprising coating the resin composition on the reinforcing material. In some exemplery examples, the heating is baking heating. In some exemplery examples, the heating is heating to a semi-curing temperature. In some exemplery examples, the semi-curing temperature may be between 100° C. and 200° C. In some exemplery examples, the reinforcing material may be a fibrous material, a woven fabric, a non-woven fabric, or a combination thereof, and the present invention is not limited thereto. In some exemplery examples, the woven fabric may comprise a fiberglass fabric. There is no particular limitation on the type of fiberglass fabric, and it may be commercially available fiberglass fabric used for various printed circuit boards. In some exemplery examples, the fiberglass fabric may be an E-type glass fabric, a D-type glass fabric, an S-type glass fabric, a T-type glass fabric, an L-type glass fabric, or a Q-type glass fabric (i.e., quartz fiber fabric), where the type of fibers comprises yarns or rovings and the like, and the form may comprise splitting or non-splitting. In some exemplery examples, the woven fabric comprises a liquid crystal resin woven fabric. In some exemplery examples, the liquid crystal resin woven fabric comprises a polyester woven fabric, a polyurethane woven fabric, or a combination thereof, and the present invention is not limited thereto. In some exemplery examples, the non-woven fabric comprises a liquid crystal resin non-woven fabric. In some exemplery examples, the liquid crystal resin non-woven fabric comprises a polyester non-woven fabric, a polyurethane non-woven fabric, or a combination thereof, and the present invention is not limited thereto. In some exemplery examples, the reinforcing material may increase the mechanical strength of the prepreg. In some exemplery examples, the reinforcing material is pre-treated with the silane coupling agent.

In some exemplery examples, the present application provides a resin film. In one aspect, the present application provides the use of the copolymer of the present application or the resin composition of the present application in preparing the resin film. In some exemplery examples, the resin film comprises the resin composition in the semi-cured state. In some exemplery examples, a method of preparing the resin film is provided, comprising semi-curing the resin composition, particularly heating the resin composition. In some exemplery examples, the method of preparing the resin film further comprises coating the resin composition on a substrate. In some exemplery examples, a resin film combination is provided, comprising the substrate and the resin film provided on the substrate. In some exemplery examples, a method of preparing the resin film combination is provided, comprising providing the substrate and providing the resin film on the substrate. In some exemplery examples, the providing the resin film on the substrate comprises: coating the resin composition to the substrate, and semi-curing the resin composition, particularly heating the resin composition. In some exemplery examples, the substrate may be a polyethylene terephthalate film (PET film), a polyimide film (PI film), a copper foil, a resin-coated copper foil, or a combination thereof, but the present invention is not limited thereto. In some exemplery examples, the heating is baking heating. In some exemplery examples, the heating is heating to a semi-curing temperature. In some exemplery examples, the semi-curing temperature may be between 100° C. and 200° C.

In some exemplery examples, the present application provides a laminate. In one aspect, the present application provides the use of the copolymer of the present application or the resin composition of the present application in preparing the laminate. In some exemplery examples, the laminate comprises at least two pieces of metal foil and an insulating layer provided between the metal foils. In some exemplery examples, the insulating layer separates the metal foils. In some exemplery examples, the metal foil may comprise copper, aluminum, nickel, platinum, silver, gold, or alloys thereof. In some exemplery examples, the metal foil may be a copper foil. In some exemplery examples, the insulating layer may be obtained by heating and curing the aforementioned resin composition or the aforementioned resin composition in the semi-cured state. In some exemplery examples, the heating is baking heating. In some exemplery examples, the heating and curing is heating to a curing temperature. In some exemplery examples, the curing temperature may be between 180° C. and 250° C., particularly between 200° C. and 230° C. In some exemplery examples, the curing time is 90 to 180 minutes, particularly 120 to 150 minutes. In some exemplery examples, the curing comprises applying pressure to the semi-cured resin composition. In some exemplery examples, the insulating layer may be formed from the aforementioned prepreg or resin film after curing. In some exemplery examples, the laminate is a copper clad laminate (CCL).

In some exemplery examples, the laminate may be further processed through a wiring process to form a circuit board, such as the printed circuit board. A procedure to manufacture the printed circuit board of the present application may be providing a double-sided copper clad laminate having a thickness of 28 mil and a 0.5 ounce hyper very low profile (HVLP) copper foil (such as product EM-890, available from Elite Material), and drilling and electroplating to provide electrical communication between a top copper foil and a bottom copper foil. And then, etching the top copper foil and the bottom copper foil to form an inner circuit. Then, browning and roughening The inner circuit, to form a concave-convex structure on the surface to increase roughness. Then, sequentially stacking the copper foil, the aforementioned prepreg, the aforementioned inner circuit board, the aforementioned prepreg, and the copper foil, and heating at a temperature of 180° C. to 250° C. for 90 to 180 minutes using a vacuum laminating apparatus to cure the insulating layer material of the prepreg. Then, various circuit board processes known in the art, such as blackening, drilling, and copper plating are performed on the copper foil at the outermost surface to obtain the printed circuit board.

In some exemplery examples, the present application provides a cured insulator. In one aspect, the present application provides the use of the copolymer of the present application or the resin composition of the present application in preparing the cured insulator. In some exemplery examples, a method of preparing the cured insulator is provided, comprising: curing the resin composition directly or through multiple curing processes. In some exemplery examples, the multiple curing refers to greater than or equal to two times of curing. For instance, the resin composition may be first semi-cured, particularly by heating the resin composition to obtain the semi-cured resin composition. Then, the semi-cured resin composition is further cured, especially heating the semi-cured resin composition. In some exemplery examples, the cured insulator comprises the resin composition in the cured state, the resin composition in the cured state containing the reinforcing material, or a combination thereof.

In some exemplery examples, the heating is baking heating. In some exemplery examples, the semi-curing the resin composition is heating to a semi-curing temperature. In some exemplery examples, the semi-curing temperature may be between 100° C. and 200° C. In some exemplery examples, the directly curing the resin composition or curing the semi-cured resin composition is heating to a curing temperature. In some exemplery examples, the curing temperature may be between 180° C. and 250° C., particularly between 200° C. and 230° C. In some exemplery examples, the curing time is 90 to 180 minutes, particularly 120 to 150 minutes. In some exemplery examples, the curing comprises applying pressure to the resin composition or the semi-cured resin composition.

In some exemplery examples, the cured insulator comprises the resin composition in the cured state. In some exemplery examples, a method of preparing the cured insulator is provided, comprising: curing the resin film, particularly heating the resin film. In some exemplery examples, a method of preparing the cured insulator is provided, comprising: semi-curing the resin composition, particularly heating the resin composition to form the resin film; and curing the resin film, particularly heating the resin film. In some exemplery examples, the method of preparing the cured insulator further comprises coating the resin composition on a laminate substrate, semi-curing the resin composition, particularly heating the resin composition to form the resin film; and curing the resin film, particularly heating the resin film.

In some exemplery examples, the cured insulator comprises the resin composition in the cured state containing the reinforcing material. In some exemplery examples, a method of preparing the cured insulator is provided, comprising: curing the prepreg, particularly heating the prepreg. In some exemplery examples, a method of preparing the cured insulator is provided, comprising: providing the resin composition on the reinforcing material, and semi-curing the resin composition, particularly heating the resin composition to form the prepreg comprising the reinforcing material and the semi-cured layer; and curing the prepreg, particularly heating the prepreg.

In some exemplery examples, the method of preparing the cured insulator further comprises molding. For instance, the resin composition or the semi-cured resin composition may be put into a mold and shaped and cured in the mold at the curing temperature and a certain pressure, thereby obtaining a cured insulator of a particular shape.

In some exemplery examples, the cured insulator is an insulating layer with no metal on the surface of the aforementioned laminate or the printed circuit board after removing the surface metal foil.

### EXAMPLES

The following examples are only used to illustrate the embodiments of the present invention and are not used to limit the present invention.

### Raw Materials and Synthesis Thereof

The chemical raw materials used in the following examples have the following structures and sources:
phenyltrivinylsilane: as shown in the structure of formula (1), available from SISO.
diphenyldivinylsilane: as shown in the structure of formula (2), available from SISO.
methyltrivinylsilane: commercially available from any source.
tetraphenyldivinyldisiloxane: commercially available from any source.
2,4-diphenyl-4-methyl-1-pentene: as shown in the structure of formula (4), available from Aladdin.

2,4-diphenyl-3,4-dimethyl-1-hexene: as shown in the structure of formula (5), synthesized according to the following synthesis example 1.

2,4-di(p-methoxy)phenyl-4-methyl-1-pentene: as shown in the structure of formula (6), synthesized according to the following synthesis example 2.

1,4-naphthoquinone: available from Aladdin.

n-dodecylmercaptan: available from Aladdin.

SA9000: bis(methacrylate)-terminated polyphenylene ether resin, available from Sabic.

OPE-2st 1200: bis-vinylbenzyl-terminated polyphenylene ether resin, available from Sabic.

TUFTEC® H1051: hydrogenated styrene-butadiene-styrene triblock copolymer (SEBS), available from Asahi Kasei.

MD1648: hydrogenated styrene-butadiene-styrene triblock copolymer (SEBS), available from Kraton.

SBS-C: styrene-butadiene-styrene triblock copolymer, available from Nippon Soda.

EBT-4045M: ethylene propylene diene monomer, available from Sinopec Mitsui Chemicals.

Ricon 100: styrene-butadiene copolymer, available from Cray Valley.

Ricon 184MA6: maleic anhydride-adducted with styrene-butadiene copolymer, available from Cray Valley.

Ricon 257: styrene-butadiene-divinylbenzene terpolymer, available from Cray Valley.

SC-2050 SMJ: spherical silica having a surface treated with a silane coupling agent, available from Admatechs.

25B: 2,5-dimethyl-2,5-di(tert-butylperoxy)-3-hexyne, available from NOF Corporation.

butanone: commercially available from any source.

toluene: available from Champion Benefit Enterprises.

### Synthesis Example 1

20 g of but-1-en-2-ylbenzene (available from Aladdin) and 10 g of toluene were added into a flask and stirred to mix uniformly, 0.2 g of p-toluenesulfonic acid monohydrate was added, N₂ was displaced into the flask, the temperature was maintained at 20° C., the reaction proceeded for 20 hours, and a small amount of pure water was added to terminate the reaction. The reaction mixture was diluted with 20 g of ethyl acetate, the organic phase was washed with pure water to remove impurities, and then dried, filtered, and rotary evaporated to remove the solvent to obtain the compound having the structure shown in formula (5).

### Synthesis Example 2

Substantially the same as synthesis example 1 except that but-1-en-2-ylbenzene was replaced with 20 g of 1-isopropenyl-4-methoxybenzene (available from Aladdin), and the compound having the structure shown in formula (6) was obtained after synthesis.

### Preparation of Copolymers

Parts by weight of the raw materials of the preparation examples and the comparative preparation examples of the copolymers prepared in the present application are shown in table 1. The blank in the table indicates “0”.

TABLE 1

| | Examples | | | | | | | | | | | | | | | | | |
|---|---|---|---|---|---|---|---|---|---|---|---|---|---|---|---|---|---|---|
| Raw materials | Preparation examples | | | | | | | | | Comparative preparation examples | | | | | | | | |
| (parts by weight) | 1 | 2 | 3 | 4 | 5 | 6 | 7 | 8 | 9 | 1 | 2 | 3 | 4 | 5 | 6 | 7 | 8 | 9 |
| Phenyltrivinylsilane | 98 | 95 | 90 | 85 | 80 | 60 | | 90 | 90 | 100 | | | 75 | | | | 90 | 90 |
| Diphenyldivinylsilane | | | | | | 30 | 90 | | | | | 100 | | | | | | |
| Methyltrivinylsilane | | | | | | | | | | | | | | 90 | | | | |
| Tetraphenyldivinylsiloxane | | | | | | | | | | | | | | | 90 | | | |
| Vinyltriethoxysilane | | | | | | | | | | | | | | | | 90 | | |
| 2,4-diphenyl-4-methyl-1-pentene | 2 | 5 | 10 | 15 | 20 | 10 | 10 | | | | 100 | | 25 | 10 | 10 | 10 | | |
| 2,4-diphenyl-3,4-dimethyl-1- | | | | | | | | 10 | | | | | | | | | | |
| hexene | | | | | | | | | | | | | | | | | | |
| 2,4-di(p-methoxy) phenyl-4- | | | | | | | | | 10 | | | | | | | | | |
| methyl-1-pentene | | | | | | | | | | | | | | | | | | |
| 1,4-naphthoquinone | | | | | | | | | | | | | | | | | 10 | |
| N-dodecylmercaptan | | | | | | | | | | | | | | | | | | 10 |

### Preparation Example 1

Under a nitrogen atmosphere, 98 parts by weight of phenyltrivinylsilane, 2 parts by weight of 2,4-diphenyl-4-methyl-1-pentene, 0.5 parts by weight of 2,5-dimethyl-2,5-di(tert-butylperoxy)-3-hexyne (25B), and 40 parts by weight of toluene were added into a three-neck flask, heated to a temperature of 120° C., stirred for 5 hours, and then cooled to room temperature after the completion of the reaction to obtain a crude reaction product 1.

Under stirring, the crude product 1 was slowly poured into absolute ethanol to precipitate a white precipitate, and a white solid 1 was obtained by suction filtration and washing with absolute ethanol. The obtained white solid 1 was placed in a vacuum drying oven at 50° C. to 70° C. for 6 hours to 10 hours, and the residual solvent was removed. The obtained white solid 2 (namely, the product 2) is copolymer 1. A content of a structural unit formed from phenyltrivinylsilane was 98 mol %.

### Preparation Example 2

95 parts by weight of phenyltrivinylsilane and 5 parts by weight of 2,4-diphenyl-4-methyl-1-pentene were added into a three-neck flask, and the other raw materials and steps were the same as in preparation example 1 to obtain copolymer 2. A content of a structural unit formed from phenyltrivinylsilane was 96 mol %.

### Preparation Example 3

90 parts by weight of phenyltrivinylsilane and 10 parts by weight of 2,4-diphenyl-4-methyl-1-pentene were added into a three-neck flask, and the other raw materials and steps were the same as in preparation example 1 to obtain copolymer 3. A content of a structural unit formed from phenyltrivinylsilane was 92 mol %.

### Preparation Example 4

85 parts by weight of phenyltrivinylsilane and 15 parts by weight of 2,4-diphenyl-4-methyl-1-pentene were added into a three-neck flask, and the other raw materials and steps were the same as in preparation example 1 to obtain copolymer 4. A content of a structural unit formed from phenyltrivinylsilane was 88 mol %.

### Preparation Example 5

80 parts by weight of phenyltrivinylsilane and 20 parts by weight of 2,4-diphenyl-4-methyl-1-pentene were added into a three-neck flask, and the other raw materials and steps were the same as in preparation example 1 to obtain copolymer 5. A content of a structural unit formed from phenyltrivinylsilane was 84 mol %.

### Preparation Example 6

60 parts by weight of phenyltrivinylsilane, 30 parts by weight of diphenyldivinylsilane, and 10 parts by weight of 2,4-diphenyl-4-methyl-1-pentene were added into a three-neck flask, and the other raw materials and steps were the same as in preparation example 1 to obtain copolymer 6. A content of a structural unit formed from phenyltrivinylsilane and diphenyldivinylsilane was 91 mol %.

### Preparation Example 7

90 parts by weight of diphenyldivinylsilane and 10 parts by weight of 2,4-diphenyl-4-methyl-1-pentene were added into a three-neck flask, and the other raw materials and steps were the same as in preparation example 1 to obtain copolymer 7. A content of a structural unit formed from diphenyldivinylsilane was 90 mol %.

### Preparation Example 8

90 parts by weight of phenyltrivinylsilane and 10 parts by weight of 2,4-diphenyl-3,4-dimethyl-1-hexene were added into a three-neck flask, and the other raw materials and steps were the same as in preparation example 1 to obtain copolymer 8. A content of a structural unit formed from phenyltrivinylsilane was 92 mol %.

### Preparation Example 9

90 parts by weight of phenyltrivinylsilane and 10 parts by weight of 2,4-di(p-methoxy)phenyl-4-methyl-1-pentene were added into a three-neck flask, and the other raw materials and steps were the same as in preparation example 1 to obtain copolymer 9. A content of a structural unit formed from phenyltrivinylsilane was 93 mol %.

### Comparative Preparation Example 1

100 parts by weight of phenyltrivinylsilane were added into a three-neck flask without adding 2,4-diphenyl-4-methyl-1-pentene, and the other raw materials and steps were the same as in preparation example 1 to obtain comparative polymer 1.

### Comparative Preparation Example 2

100 parts by weight of 2,4-diphenyl-4-methyl-1-pentene were added into a three-neck flask without adding phenylvinylsilane, and the other raw materials and steps were the same as in preparation example 1 to obtain comparative polymer 2.

### Comparative Preparation Example 3

100 parts by weight of diphenyldivinylsilane were added into a three-neck flask without adding 2,4-diphenyl-4-methyl-1-pentene, and the other raw materials and steps were the same as in preparation example 1 to obtain comparative polymer 3.

### Comparative Preparation Example 4

75 parts by weight of phenyltrivinylsilane and 25 parts by weight of 2,4-diphenyl-4-methyl-1-pentene were added into a three-neck flask, and the other raw materials and steps were the same as in preparation example 1 to obtain comparative polymer 4.

### Comparative Preparation Example 5

90 parts by weight of methyltrivinylsilane and 10 parts by weight of 2,4-diphenyl-4-methyl-1-pentene were added into a three-neck flask, and the other raw materials and steps were the same as in preparation example 1 to obtain comparative polymer 5.

### Comparative Preparation Example 6

90 parts by weight of tetraphenyl divinyl siloxane and 10 parts by weight of 2,4-diphenyl-4-methyl-1-pentene were added into a three-neck flask, and the other raw materials and steps were the same as in preparation example 1 to obtain comparative polymer 6.

### Comparative Preparation Example 7

90 parts by weight of vinyltriethoxysilane and 10 parts by weight of 2,4-diphenyl-4-methyl-1-pentene were added into a three-neck flask, and the other raw materials and steps were the same as in preparation example 1 to obtain comparative polymer 7.

### Comparative Preparation Example 8

90 parts by weight of phenyltrivinylsilane and 10 parts by weight of 1,4-naphthoquinone were added into a three-neck flask, and the other raw materials and steps were the same as in preparation example 1 to obtain comparative polymer 8.

### Comparative Preparation Example 9

90 parts by weight of phenyltrivinylsilane and 10 parts by weight of n-dodecylmercaptan were added into a three-neck flask, and the other raw materials and steps were the same as in preparation example 1 to obtain comparative polymer 9.

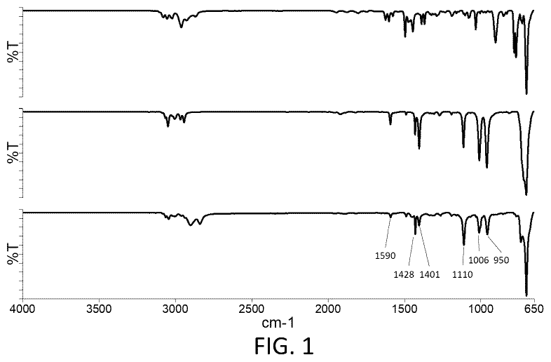

FIG. 1 is infrared spectrograms of copolymer 3, phenyltrivinylsilane, and 2,4-diphenyl-4-methyl-1-pentene, wherein the upper one is the infrared spectrogram of 2,4-diphenyl-4-methyl-1-pentene, the middle one is the infrared spectrogram of phenyltrivinylsilane, and the lower one is the infrared spectrogram of copolymer 3. In the three infrared spectrograms, an infrared characteristic absorption peak of “C═C” double bond is at 1590 cm⁻¹; compared with the upper 2,4-diphenyl-4-methyl-1-pentene and the middle phenyltrivinylsilane, the infrared characteristic absorption peak of “C═C” double bond at 1590 cm⁻¹ of the lower copolymer 3 is obviously weakened, indicating that some “C═C” double bonds have undergone addition reaction. In addition, infrared characteristic absorption peaks of “phenyl-Si” are at 1428 cm⁻¹ and 1110 cm⁻¹, and infrared characteristic absorption peaks of “vinyl-Si” are at 1401 cm⁻¹, 1006 cm⁻¹, and 950 cm⁻¹; by comparing the middle infrared spectrogram of phenyltrivinylsilane and the lower infrared spectrogram of copolymer 3, it can be seen that there is no obvious difference in the intensity of the characteristic absorption peaks of “phenyl-Si”, but the characteristic absorption peak of “vinyl-Si” of the copolymer 3 is obviously weaker than that of the phenyltrivinylsilane, which also indicates that some vinyl in the copolymer 3 has undergone addition reaction.

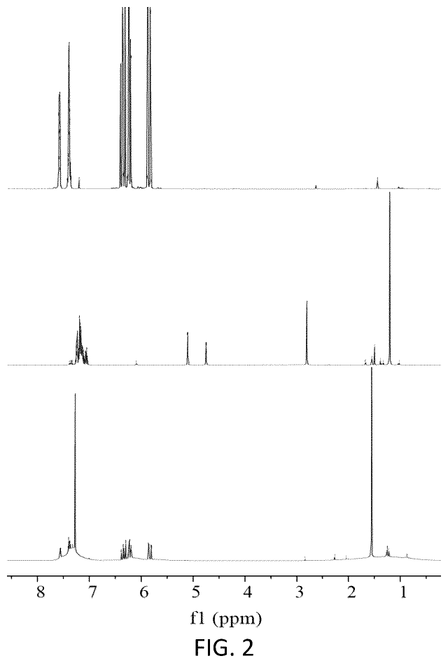

FIG. 2 is ¹H NMR spectra of copolymer 3, phenyltrivinylsilane, and 2,4-diphenyl-4-methyl-1-pentene (standard substance: tetramethylsilane (TSM)), wherein the upper one is the ¹H NMR spectrum of phenyltrivinylsilane, the middle one is the ¹H NMR spectrum of 2,4-diphenyl-4-methyl-1-pentene, and the lower one is the ¹H NMR spectrum of copolymer 3. A characteristic peak region of a benzene ring is at 7.0-7.5 ppm, a characteristic peak region of “C═C” is at 4.5-6.5 ppm (5.5-6.5 ppm for phenyltrivinylsilane and copolymer 3, and 4.5-5.5 ppm for 2,4-diphenyl-4-methyl-1-pentene), and a characteristic peak region of “—CH₃” is at 1.0-1.5 ppm. Comparing the three spectra, it can be seen that the characteristic peak of “C═C” of the copolymer 3 at 5.5-6.5 ppm is obviously weaker than that of phenyltrivinylsilane, the characteristic peak of “C═C” of 2,4-diphenyl-4-methyl-1-pentene at 4.5-5.5 ppm disappears after copolymerization, and the copolymer 3 spectrum only shows the characteristic peak of “—CH₃” from 2,4-diphenyl-4-methyl-1-pentene at 1.5 ppm; therefore, it can be seen that phenyltrivinylsilane and 2,4-diphenyl-4-methyl-1-pentene is copolymerized to generate a phenyltrivinylsilane-2,4-diphenyl-4-methyl-1-pentene copolymer (i.e., copolymer 3).

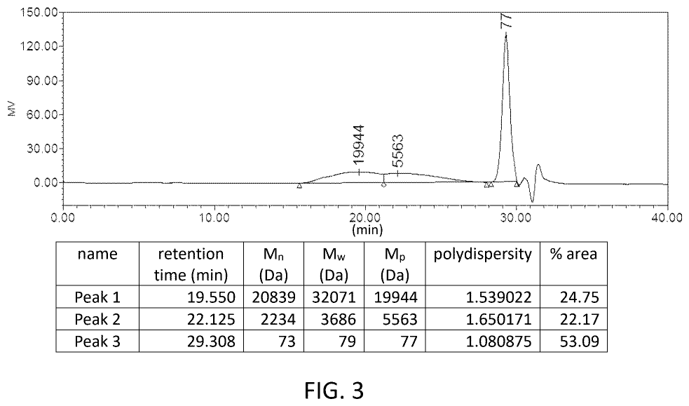

FIG. 3 is a gel permeation chromatogram of the crude reaction product of copolymer 3. It can be seen from the spectrum that the crude reaction product contains polymer molecules with weight average molecular weights of 32,071 and 3,686, which proves that the weight average molecular weight of the copolymer 3 in the present application is significantly greater than that of the raw monomers, so the copolymer 3 does copolymerize.

### Test of Copolymers/Comparative Polymers

### Non-Volatile Test Method

1 g of unpurified crude product of a copolymer of a preparative example/a comparative polymer of a comparative preparative example or an unreacted monomer compound was weighed in a tray, which contains a theoretical value of a1 g of solvent and a theoretical weight of (1−a1) g of the non-solvent portion. After baking in an oven at 170° C. for 1 hour, a2 g was weighed after cooling, and the non-volatile was calculated as [a2/(1−a1)]×100%. The results were shown in table 2.

TABLE 2
Non-volatile test results of crude products of copolymers of
preparation examples, polymers of comparative preparation
examples, and monomers

| | | Non- |
|---|---|---|
| | Components | volatile |
| Crude product of | Phenyltrivinylsilane: | 30-80% |
| preparative example 3 | 2,4-diphenyl-4-methyl-1-pentene = | |
| | 90:10 copolymer | |
| Crude product of | Diphenyldivinylsilane: 2,4- | 30-80% |
| preparative example 7 | diphenyl-4-methyl-1-pentene = | |
| | 90:10 copolymer | |
| Crude product of | Phenyltrivinylsilane homopolymer | 10-30% |
| comparative | | |
| preparation example 1 | | |
| Crude product of | 2,4-diphenyl-4-methyl-1-pentene | 10-30% |
| comparative | homopolymer | |
| preparation example 2 | | |
| Crude product of | Diphenyldivinylsilane | 10-30% |
| comparative | homopolymer | |
| preparation example 3 | | |
| Monomer compounds | Phenyltrivinylsilane | <1% |
| | 2,4-diphenyl-4-methyl-1-pentene | <1% |
| | Diphenyldivinylsilane | <1% |

It can be seen that the non-volatiles of the copolymers of the preparation examples are significantly increased and the volatility is greatly reduced compared to the phenylvinylsilane and 2,4-diphenyl-4-methyl-1-pentene of the monomers and the homopolymers of these monomers.

Phenylvinylsilane and 2,4-diphenyl-4-methyl-1-pentene are low-viscosity liquids at room temperature with low boiling points and easily volatilize when they are directly baked at a high temperature above 150° C.; meanwhile, when phenylvinylsilane or 2,4-diphenyl-4-methyl-1-pentene is homopolymerized, a monomer conversion rate is low, an homopolymerization reaction is difficult to control, and a copolymer with a uniform molecular weight cannot be obtained, thus the non-volatile thereof is also low.

Copolymers having suitable molecular weights and being less volatile at high temperatures may be obtained by copolymerization of phenylvinylsilane and 2,4-diphenyl-4-methyl-1-pentene.

### Preparation of Resin Compositions and Products Thereof

Components of compositions of examples E1 to E22 and comparative examples C1 to C15 are shown in table 3.

TABLE 3
Components of resin compositions of examples E1 to E22 and comparative examples C1 to C15 (unit: parts by weight)

| | | Examples | | | | | | | | | | | | |
|---|---|---|---|---|---|---|---|---|---|---|---|---|---|---|
| Components | | E1 | E2 | E3 | E4 | E5 | E6 | E7 | E8 | E9 | E10 | E11 | E12 | E13 |
| Copolymers | Copolymer 1 | 100 | | | | | | | | | | | | |
| | Copolymer 2 | | 100 | | | | | | | | | | | |
| | Copolymer 3 | | | 100 | | | | | | | 100 | 100 | 100 | 100 |
| | Copolymer 4 | | | | 100 | | | | | | | | | |
| | Copolymer 5 | | | | | 100 | | | | | | | | |
| | Copolymer 6 | | | | | | 100 | | | | | | | |
| | Copolymer 7 | | | | | | | 100 | | | | | | |
| | Copolymer 8 | | | | | | | | 100 | | | | | |
| | Copolymer 9 | | | | | | | | | 100 | | | | |
| Vinyl- | SA9000 | 35 | 35 | 35 | 35 | 35 | 35 | 35 | 35 | 35 | 15 | 70 | 35 | 35 |
| containing | OPE-2st 1200 | | | | | | | | | | | | | |
| polyphenylene | | | | | | | | | | | | | | |
| ether | | | | | | | | | | | | | | |
| Polyolefin | TUFTEC ®H1051 | 65 | 65 | 65 | 65 | 65 | 65 | 65 | 65 | 65 | 65 | 65 | 30 | 100 |
| | MD1648 | | | | | | | | | | | | | |
| | SBS-C | | | | | | | | | | | | | |
| | EBT-4045M | | | | | | | | | | | | | |
| | Ricon 100 | | | | | | | | | | | | | |
| | Ricon 184MA6 | | | | | | | | | | | | | |
| | Ricon 257 | | | | | | | | | | | | | |
| Filler | SC-2050 SMJ | Z*1.0 | Z*1.0 | Z*1.0 | Z*1.0 | Z*1.0 | Z*1.0 | Z*1.0 | Z*1.0 | Z*1.0 | Z*1.0 | Z*1.0 | Z*1.0 | Z*1.0 |
| Accelerant | 25B | 0.6 | 0.6 | 0.6 | 0.6 | 0.6 | 0.6 | 0.6 | 0.6 | 0.6 | 0.6 | 0.6 | 0.6 | 0.6 |
| Solvent | Butanone | q.s. | q.s. | q.s. | q.s. | q.s. | q.s. | q.s. | q.s. | q.s. | q.s. | q.s. | q.s. | q.s. |
| | Toluene | q.s. | q.s. | q.s. | q.s. | q.s. | q.s. | q.s. | q.s. | q.s. | q.s. | q.s. | q.s. | q.s. |

| | | Examples | | | | | | | | |
|---|---|---|---|---|---|---|---|---|---|---|
| Components | | E14 | E15 | E16 | E17 | E18 | E19 | E20 | E21 | E22 |
| Copolymers | Copolymer 1 | | | | | | | | | |
| | Copolymer 2 | | | | | | | | | |
| | Copolymer 3 | 100 | 100 | 100 | 100 | 100 | 100 | 100 | 100 | 100 |
| | Copolymer 4 | | | | | | | | | |
| | Copolymer 5 | | | | | | | | | |
| | Copolymer 6 | | | | | | | | | |
| | Copolymer 7 | | | | | | | | | |
| | Copolymer 8 | | | | | | | | | |
| | Copolymer 9 | | | | | | | | | |
| Vinyl- | SA9000 | 35 | 35 | 35 | 35 | 35 | 35 | | 35 | 35 |
| containing | OPE-2st 1200 | | | | | | | | | |
| polyphenylene | | | | | | | | | | |
| ether | | | | | | | | 35 | | |
| Polyolefin | TUFTEC ®H1051 | | | | | 45 | 50 | 65 | 65 | 65 |
| | MD1648 | 65 | | | | | | | | |
| | SBS-C | | 65 | | | | | | | |
| | EBT-4045M | | | 65 | | | | | | |
| | Ricon 100 | | | | 65 | | | | | |
| | Ricon 184MA6 | | | | | 20 | | | | |
| | Ricon 257 | | | | | | 15 | | | |
| Filler | SC-2050 SMJ | Z*1.0 | Z*1.0 | Z*1.0 | Z*1.0 | Z*1.0 | Z*1.0 | Z*1.5 | Z*0.5 | Z*1.0 |
| Accelerant | 25B | 0.6 | 0.6 | 0.6 | 0.6 | 0.6 | 0.6 | 0.3 | 0.6 | 1.2 |
| Solvent | Butanone | q.s. | q.s. | q.s. | q.s. | q.s. | q.s. | q.s. | q.s. | q.s. |
| | Toluene | q.s. | q.s. | q.s. | q.s. | q.s. | q.s. | q.s. | q.s. | q.s. |

| | | Comparative examples | | | | | | | | | |
|---|---|---|---|---|---|---|---|---|---|---|---|
| Components | | C1 | C2 | C3 | C4 | C5 | C6 | C7 | C8 | C9 | C10 |
| Comparative | Comparative Polymer 1 | 100 | | | | | | | | | |
| polymers | Comparative Polymer 2 | | 100 | | | | | | | | |
| | Comparative Polymer 3 | | | 100 | | | | | | | |
| | Comparative Polymer 4 | | | | 100 | | | | | | |
| | Comparative Polymer 5 | | | | | 100 | | | | | |
| | Comparative Polymer 6 | | | | | | | | 100 | | |
| | Comparative Polymer 7 | | | | | | | | | 100 | |
| | Comparative Polymer 8 | | | | | | 100 | | | | |
| | Comparative Polymer 9 | | | | | | | 100 | | | |
| Vinyl- | SA9000 | 35 | 35 | 35 | 35 | 35 | 35 | 35 | 35 | 35 | 35 |
| containing | | | | | | | | | | | |
| polyphenylene | | | | | | | | | | | |
| ether | | | | | | | | | | | |
| Polyolefin | TUFTEC ®H1051 | 65 | 65 | 65 | 65 | 65 | 65 | 65 | 65 | 65 | 65 |
| Diphenyldivinylsilane | | | | | | | | | | | |
| Phenyltrivinylsilane | | | | | | | | | | | 100 |
| 2,4-diphenyl-4-methyl-1-pentene | | | | | | | | | | | |
| Filler | SC-2050 SMJ | Z*1.0 | Z*1.0 | Z*1.0 | Z*1.0 | Z*1.0 | Z*1.0 | Z*1.0 | Z*1.0 | Z*1.0 | Z*1.0 |
| Accelerant | 25B | 0.6 | 0.6 | 0.6 | 0.6 | 0.6 | 0.6 | 0.6 | 0.6 | 0.6 | 0.6 |
| Solvent | Butanone | q.s. | q.s. | q.s. | q.s. | q.s. | q.s. | q.s. | q.s. | q.s. | q.s. |
| | Toluene | q.s. | q.s. | q.s. | q.s. | q.s. | q.s. | q.s. | q.s. | q.s. | q.s. |

| | | | Comparative examples | | | | |
|---|---|---|---|---|---|---|---|
| | Components | | C11 | C12 | C13 | C14 | C15 |
| | Comparative | Comparative Polymer 1 | | | | | |
| | polymers | Comparative Polymer 2 | | | | | |
| | | Comparative Polymer 3 | | | | | |
| | | Comparative Polymer 4 | | | | | |
| | | Comparative Polymer 5 | | | | | |
| | | Comparative Polymer 6 | | | | | |
| | | Comparative Polymer 7 | | | | | |
| | | Comparative Polymer 8 | | | | | |
| | | Comparative Polymer 9 | | | | | |
| | Vinyl- | SA9000 | 35 | 35 | 35 | 35 | 35 |
| | containing | | | | | | |
| | polyphenylene | | | | | | |
| | ether | | | | | | |
| | Polyolefin | TUFTEC ®H1051 | 65 | 65 | 65 | 65 | 65 |
| Diphenyldivinylsilane | | | | | 100 | 90 | 30 |
| Phenyltrivinylsilane | | | | 90 | | | 60 |
| 2,4-diphenyl-4-methyl-1-pentene | | | 100 | 10 | | 10 | 10 |
| | Filler | SC-2050 SMJ | Z*1.0 | Z*1.0 | Z*1.0 | Z*1.0 | Z*1.0 |
| | Accelerant | 25B | 0.6 | 0.6 | 0.6 | 0.6 | 0.6 |
| | Solvent | Butanone | q.s. | q.s. | q.s. | q.s. | q.s. |
| | | Toluene | q.s. | q.s. | q.s. | q.s. | q.s. |

“Z” in table 3 represents a total amount of all other components excluding (i.e., not including) the inorganic filler and the solvent in the resin composition of each example or comparative example. In the table, “Z*1.0” represents that an addition amount of the inorganic filler is 1.0 times the aforementioned Z. For instance, Z*1.0 in example E1 represents that the addition amount of the inorganic filler is 200 parts by weight (200 parts by weight multiplied by 1.0).

An addition amount of butanone and toluene in table 3 is “q.s.” (quantum satis), which represents the amount of solvent used when the solvent is added in such a way that the overall solid content of the resin composition is the ideal solid content. For resin compositions using both butanone and toluene, “q.s.” represents a total amount of these three solvents making the overall solid content of the resin composition being the ideal solid content, such as but the present invention is not limited to 70% by weight.

The method of preparing the resin compositions of examples E1 to E22 and comparative Examples C1 to C15 are as follows.

### Preparation of Varnish

Components of examples E1 to E22 or comparative examples C1 to C15 were added to a stirring tank according to the amounts in table 3 for stirring and uniformly mixed to form a resin composition referred to as a resin varnish.

Taking example E1 as an example, 100 parts by weight of copolymer 1 and 35 parts by weight of dimethacrylate-terminated polyphenylene ether resin (SA9000) were added into a stirrer containing appropriate amounts of toluene and butanone and stirred until the solid components were completely dissolved. Then, 65 parts by weight of TUFTEC® H1051 were added and stirred uniformly, and “Z*1.0” parts by weight of spherical silica SC-2050 SMJ (i.e., 200 parts by weight) were added and stirred until completely dispersed, and then 0.6 parts by weight of curing accelerator (25B, an appropriate amount of solvent was used to dissolve the curing accelerator to a solution) were added and stirred for 1 hour to obtain a varnish of the resin composition E1.

Further, the varnishes of the other examples E2 to E22 and comparative examples C1 to C15 were prepared referring to the method of preparing the varnish of example E1 according to the amounts of the components listed in table 3.

### Preparation of Prepreg-1 (by 2116 L-Fiberglass Fabric)

The varnishes of the resin compositions of examples E1 to E22 and comparative examples C1 to C15 were placed in an impregnation tank, a fiberglass fabric (such as L-fiberglass fabric having a specification of 2116) was passed through the impregnation tank, and the varnishes were attached to the fiberglass fabric and heated to a semi-cured (B-Stage) at 120° C. to 170° C. to obtain a prepreg-1 (resin content about 52%).

### Preparation of Prepreg-2 (by 1035 Q-Fiberglass Fabric)

The varnishes of the resin compositions of examples E1 to E22 and comparative examples C1 to C15 were placed in the impregnation tank, a fiberglass fabric (such as Q-fiberglass fabric having a specification of 1035) was passed through the impregnation tank, and the varnishes were attached to the fiberglass fabric and heated to a semi-cured (B-Stage) at 120° C. to 170° C. to obtain a prepreg 2 (resin content about 80%).

### Preparation of Copper Clad Laminate-1 (Formed by Pressing Eight Prepreg-1)

Two hyper very low profile 3 copper foils (HVLP3 copper foils) having a thickness of 18 μm (Hoz) and eight prepreg-1 prepared from the resin compositions of the examples and comparative examples were prepared in batches. A copper clad laminate-1 was formed by laminating in an order of “one aforementioned copper foil/eight prepreg-1/one aforementioned copper foil” under vacuum conditions at 200° C. for 130 minutes. The eight laminated prepreg-1 were cured (C-stage) to form an insulating layer between two copper foils, and the resin content of the insulating layer was about 52%.

### Preparation of Copper Clad Laminate-2 (Formed by Pressing Two Prepreg 2)

Two HVLP3 copper foils having a thickness of 18 μm and two prepreg-2 prepared from the resin compositions were prepared in batches. A copper clad laminate-2 was formed by laminating in an order of “one aforementioned copper foil/two prepreg-2/one aforementioned copper foil” under vacuum conditions at 200° C. for 130 minutes. The two laminated prepreg-2 were cured (C-stage) to form an insulating layer between two copper foils, and the resin content of the insulating layer was about 80%.

### Copper-Free Laminate-1 (Formed by Pressing Eight Prepreg-1)

The above-mentioned copper clad laminate-1 (formed by laminating eight prepreg-1) was etched to remove copper foils on two sides to obtain a copper-free laminate-1. It was formed by laminating eight prepreg-1 and had a resin content of about 52%.

### Copper-Free Laminate 2 (Formed by Pressing Two Prepreg-2)

The above-mentioned copper clad laminate 2 (formed by laminating two prepreg-2) was etched to remove copper foils on two sides to obtain a copper-free laminate-2. It was formed by laminating two prepreg-2 and had a resin content of about 80%.

### Test and Characteristic Analysis of Products

### 1. Glass Transition Temperature (Tg) Test

The “copper-free laminate-1” prepared from the resin compositions of the aforementioned examples or comparative examples were used as samples to be tested for dynamic mechanical analysis (DMA). The samples were heated at a temperature rise rate of 2° C. per minute in a temperature range from 35° C. to 300° C., and the glass transition temperature (in ° C.) of each sample to be tested was measured according to the method of IPC-TM-650 2.4.24.4.

In the art, the higher the glass transition temperature, the better. A difference in glass transition temperature greater than or equal to 5° C. represents a significant difference (significant technical difficulty) in glass transition temperature between different laminates.

2. Peeling Strength of Copper Foil (a.k.a. P/S) Test

The “copper clad laminate-1” prepared from the resin compositions of the aforementioned examples or comparative examples was cut into a rectangular sample having a width of 24 mm and a length of more than 60 mm, and the surface copper foil was etched, leaving only a strip-shaped copper foil having a width of 3.18 mm and a length of more than 60 mm. The force (in lb/in) required to pull the copper foil away from the surface of the laminate was measured using a universal tensile strength tester at a room temperature (about 25° C.) according to the method of IPC-TM-650 2.4.8.

In the art, the higher the peeling strength of copper foil, the better. A difference in peeling strength of copper foil value greater than or equal to 0.1 lb/in represents a significant difference (significant technical difficulty).

### 3. Dielectric Constant (Dk) and Dissipation Factor (Df) Test

The “copper-free laminate-2” prepared from the resin compositions of the aforementioned examples or comparative examples were used as samples to be tested, and the samples to be tested were measured at a frequency of 10 GHz using a microwave dielectrometer (available from AET, Japan) according to the method of JIS C2565.

In the art, the lower the dielectric constant or dissipation factor, the better dielectric characteristics of the sample to be tested. When dielectric constant is measured at a frequency of 10 GHz, and the dielectric constant value is less than or equal to 3.50 and the dissipation factor value is less than or equal to 0.002, a difference in dielectric constant value greater than or equal to 0.05 represents a significant difference (significant technical difficulty) between the dielectric constants of different laminates, while a difference in dielectric constant value less than 0.05 represents no significant difference in the dielectric constant of the laminates. A difference in dissipation factor value less than 5×10⁻⁵ represents no significant difference in the dissipation factors of the laminates, while a difference in dissipation factor value greater than or equal to 5×10⁻⁵ represents a significant difference (significant technical difficulty) between the dissipation factors of different laminates.

4. Ratio of Thermal Expansion (a.k.a. Ratio of Dimensional Change)

The “copper-free laminate-1” prepared from the resin compositions of the aforementioned examples or comparative examples were used as samples to be tested for thermal mechanical analysis (TMA) to measure the ratio of thermal expansion. The samples were heated at a temperature rise rate of 10° C. per minute in a temperature range from 35° C. to 265° C., and a Z-axis ratio of dimensional change (a temperature range from 50° C. to 260° C., in %) of each sample to be tested was measured according to the method of IPC-TM-650 2.4.24.5.

In the art, the lower the measured ratio of dimensional change, the better; a difference in the ratio of thermal expansion greater than or equal to 0.1% represents a significant difference (significant technical difficulty).

A large ratio of dimensional change represents a high Z-axis ratio of thermal expansion of the laminate. For the copper clad laminate, the high ratio of thermal expansion tends to cause the printed circuit board to be displaced at a line contact point (such as a blind hole or a buried via, but the present invention is not limited thereto) during the processing, reducing the yield rate, or to cause a problem such as a delamination, reducing the reliability.

5. Heat Resistance after Moisture Absorption (Pressure Cooking Test, PCT)

The “copper-free laminate-1” prepared from the resin compositions of the aforementioned examples or comparative examples were used as samples to be tested and subjected to moisture absorption for 3 hours or 5 hours (a test temperature being 121° C. and a relative humidity being 100%) through a pressure cooking test (PCT) according to the method of IPC-TM-650 2.6.16.1, and then immersed in a tin furnace at a constant temperature of 288° C. according to the method of IPC-TM-650 2.4.23, and taken out after 20 seconds of immersion to observe whether a delamination occurs, for instance, interlayer delamination or blistering occurs between insulating layers was a delamination. The interlayer delamination or blistering may cause blister separation between any layers of the laminate (visible to a person).

The glass transition temperature (Tg), peeling strength of copper foil (P/S), dielectric constant (Dk), dissipation factor (Df), ratio of thermal expansion, and heat resistance after moisture absorption (PCT) of the products prepared using the resin compositions of the examples and comparative examples of the present application are shown in table 4.

TABLE 4
Testing and characteristic analysis results of resin composition products
of various examples and comparative examples of present application

| Property test | Unit | E1 | E2 | E3 | E4 | E5 | E6 | E7 | E8 | E9 | E10 | E11 | E12 |
|---|---|---|---|---|---|---|---|---|---|---|---|---|---|
| Tg | ° C. | 237 | 234 | 225 | 220 | 210 | 196 | 175 | 220 | 230 | 218 | 247 | 247 |
| P/S | lb/in | 3.30 | 3.35 | 3.45 | 3.47 | 3.60 | 3.60 | 3.80 | 3.25 | 3.80 | 3.10 | 3.60 | 3.10 |
| Dk | | 2.93 | 2.92 | 2.90 | 2.90 | 2.85 | 2.94 | 2.90 | 2.93 | 3.00 | 2.90 | 2.96 | 2.95 |
| Df | ×10⁻⁵ | 100 | 98 | 94 | 91 | 86 | 90 | 84 | 95 | 105 | 88 | 98 | 95 |
| Ratio | % | 1.6 | 1.0 | 1.0 | 1.4 | 1.6 | 2.2 | 2.6 | 1.4 | 1.4 | 1.0 | 1.1 | 1.4 |
| of thermal | | | | | | | | | | | | | |
| expansion | | | | | | | | | | | | | |
| PCT (3 hr) | | ◯ | ◯ | ◯ | ◯ | ◯ | ◯ | ◯ | ◯ | ◯ | ◯ | ◯ | ◯ |
| PCT (5 hr) | | X | ◯ | ◯ | ◯ | X | X | X | ◯ | ◯ | ◯ | ◯ | ◯ |

| Property test | Unit | E13 | E14 | E15 | E16 | E17 | E18 | E19 | E20 | E21 | E22 |
|---|---|---|---|---|---|---|---|---|---|---|---|
| Tg | ° C. | 210 | 228 | 207 | 221 | 240 | 221 | 227 | 231 | 211 | 238 |
| P/S | lb/in | 3.40 | 3.60 | 3.10 | 3.60 | 3.20 | 3.80 | 3.50 | 3.10 | 3.60 | 3.10 |
| Dk | | 2.91 | 2.90 | 2.95 | 2.90 | 2.90 | 3.00 | 2.92 | 3.00 | 2.85 | 3.00 |
| Df | ×10⁻⁵ | 84 | 90 | 94 | 91 | 95 | 105 | 95 | 95 | 90 | 98 |
| Ratio | % | 0.7 | 1.2 | 1.4 | 0.7 | 1.4 | 1.1 | 0.8 | 1.0 | 1.4 | 0.8 |
| of thermal | | | | | | | | | | | |
| expansion | | | | | | | | | | | |
| PCT (3 hr) | | ◯ | ◯ | ◯ | ◯ | ◯ | ◯ | ◯ | ◯ | ◯ | ◯ |
| PCT (5 hr) | | ◯ | ◯ | ◯ | ◯ | ◯ | ◯ | ◯ | ◯ | ◯ | ◯ |

| Property test | Unit | C1 | C2 | C3 | C4 | C5 | C6 | C7 | C8 |
|---|---|---|---|---|---|---|---|---|---|
| Tg | ° C. | 238 | 188 | 170 | 196 | 193 | 230 | 192 | 199 |
| P/S | lb/in | 2.90 | 2.70 | 2.85 | 3.60 | 2.85 | 3.55 | 3.60 | 3.80 |
| Dk | | 2.90 | 3.15 | 3.05 | 2.92 | 3.15 | 3.20 | 3.15 | 3.15 |
| Df | ×10⁻⁵ | 110 | 90 | 95 | 111 | 106 | 136 | 168 | 131 |
| Ratio | % | 1.6 | 1.8 | 1.9 | 1.6 | 0.7 | 1.0 | 1.6 | 1.6 |
| of thermal | | | | | | | | | |
| expansion | | | | | | | | | |
| PCT (3 hr) | | ◯ | X | ◯ | X | ◯ | ◯ | ◯ | ◯ |
| PCT (5 hr) | | X | X | X | X | ◯ | ◯ | ◯ | ◯ |

| Property test | C9 | C10 | C11 | C12 | C13 | C14 | C15 |
|---|---|---|---|---|---|---|---|
| Tg | 162 | 220 | 185 | 207 | 155 | 167 | 186 |
| P/S | 4.00 | 2.60 | 2.60 | 2.60 | 2.61 | 2.53 | 2.53 |
| Dk | 3.31 | 2.90 | 3.15 | 2.95 | 2.94 | 2.95 | 2.95 |
| Df | 152 | 100 | 98 | 100 | 100 | 100 | 100 |
| Ratio | 2.8 | 2.4 | 2.2 | 2.2 | 2.8 | 2.8 | 2.6 |
| of thermal | | | | | | | |
| expansion | | | | | | | |
| PCT (3 hr) | ◯ | X | X | X | X | X | X |
| PCT (5 hr) | ◯ | X | X | X | X | X | X |

### Note:

For P/S, HVLP3 copper foils of 18 μm (Hoz) are used.

For Dk and Df, copper-free laminate 2 prepared with 1035 Q-fiberglass fabric are used and are measured at a frequency of 10 GHz, with the resin content of about 80%.

The PCT heat resistance test includes absorbing moisture for 3 or 5 hours at 121° C. and 100% relative humidity and immersing in a tin oven at a constant temperature of 288° C. for 20 seconds.

In the PCT heat resistance test, “O” means pass and “X” means fail.

It can be seen from table 4 that, the resin compositions of the present application, for instance, products made from the resin compositions of various examples of the present application,
has a glass transition temperature greater than or equal to 175° C., for instance, between 175° C. and 247° C., measured by the method described in IPC-TM-650 2.4.24.4;
has a peeling strength of copper foil greater than or equal to 3.10 lb/in, between 3.10 lb/in and 3.80 lb/in, as measured by the method of IPC-TM-650 2.4.8;
has dielectric constant less than or equal to 3.00, for instance, between 2.85 and 3.00, as measured by the method of JIS C2565 at a frequency of 10 GHz;
has a dissipation factor less than or equal to 0.00105, for instance, between 0.00084 and 0.00105, as measured by the method of JIS C2565 at a frequency of 10 GHz.
has a Z-axis ratio of thermal expansion less than or equal to 2.6%, for instance, between 0.7% and 2.6%, as measured by the method of IPC-TM-650 2.4.24.5;
there is no delamination in the heat resistance test after 3 hours of moisture absorption according to the method of IPC-TM-650 2.6.16.1 and IPC-TM-650 2.4.23 (specification requirements for industrial laminates or printed circuit boards); for some of the examples, it is possible to pass the more severe heat resistance after 5 hours of moisture absorption with no delaminatio.

It can be seen that the copolymer in some exemplery examples of the present application, in which a part of double bonds is retained, has a strong crosslinking reactivity, and can be added to the resin composition to further participate in the crosslinking reaction, and can simultaneously improve the peeling strength of copper foil and dielectric properties of the product thereof.

By comparing examples E1 to E7 with comparative examples C1 to C4, it can be confirmed that the products made from the copolymer in some exemplery examples of the present application, compared with the copolymer or homopolymer in an amount outside the above-mentioned range, can simultaneously achieve at least one of increasing the glass transition temperature, increasing the peeling strength of copper foil, decreasing the dielectric constant, decreasing the dissipation factor, and passing the 3-hour PCT test.

By comparing examples E3, E6 to E9 with comparative examples C5 to C9, it can be confirmed that the products made from the copolymer in some exemplery examples of the present application, compared with the compound having the monomer species outside the above-mentioned range, can simultaneously achieve at least one of increasing the glass transition temperature, increasing the peeling strength of copper foil, decreasing the dielectric constant, and decreasing the dissipation factor.

By comparing example E3 with comparative examples C10 to C12, example E6 with comparative example C15, and example E7 with comparative examples C11 and C13 to C14, it can be confirmed that the products made from the copolymer in some exemplery examples of the present application, compared with the addition of phenylvinylsilane alone, the addition of the vinyl-containing compound A alone, or the addition of phenylvinylsilane and the vinyl-containing compound A without copolymerization, can simultaneously achieve at least one of increasing the glass transition temperature, increasing the peeling strength of copper foil, decreasing the dielectric constant, decreasing the dissipation factor, and passing the 3-hour PCT test.

By comparing examples E1 to E22 with comparative examples C1 to C15, it can be confirmed that in the copolymers in some exemplery examples of the present application, the prepared laminate can simultaneously achieve the technical effects of the peeling strength of copper foil greater than or equal to 3.10 lb/in, the dielectric constant less than or equal to 3.0, and the dissipation factor less than or equal to 0.00105, by combining a copolymer of 80-98 parts by weight of phenylvinylsilane and 2-20 parts by weight of the vinyl-containing compound, 15-70 parts by weight of vinyl-containing polyphenylene ether, and 30-100 parts by weight of polyolefin. The comparative examples C1 to C15, which do not use the technical solution of the present invention, do not achieve the above technical effects at the same time.

What is claimed is:

1. A copolymer, comprising:
a structural unit formed from phenylvinylsilane and vinyl-containing compound A,
wherein raw materials of the copolymer comprise phenylvinylsilane and vinyl-containing compound A; based on a total weight of phenylvinylsilane and the vinyl-containing compound A being 100 parts by weight, phenylvinylsilane is 80 to 98 parts by weight, and the vinyl-containing compound A is 2 to 20 parts by weight; and
wherein, the phenylvinylsilane has a structure of formula (1) or formula (2), and the vinyl-containing compound A has a structure of formula (3), 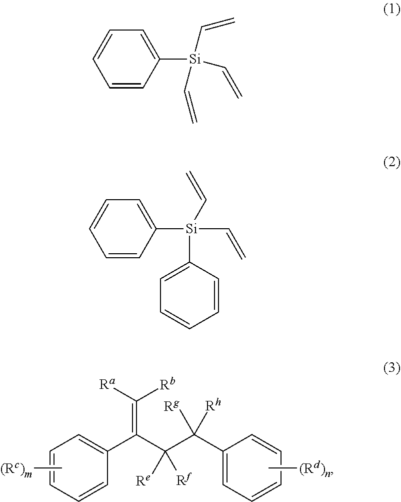
and
wherein,
R^{a}, R^{b}, R^{c}, and R^{d} are each independently H or a monovalent organic group;
m and n are each independently an integer from 0 to 5; and
R^{e}, R^{f}, R^{g}, and R^{h} are each independently H or monovalent alkyl having 1 to 4 carbon atoms.

2. The copolymer according to claim 1, wherein
the phenylvinylsilane is 85 to 95 parts by weight, and the vinyl-containing compound A is 5 to 15 parts by weight.

3. The copolymer according to claim 1, wherein
vinyl-containing compound A has a structure of formula (4), formula (5), or formula (6),

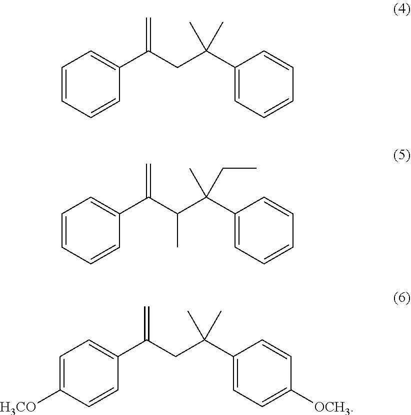

4. The copolymer according to claim 1, wherein
the copolymer comprises J1 structures of formula (7), J2 structures of formula (8), J3 structures of formula (9), K1 structures of formula (10), K2 structures of formula (11), and L1 structures of formula (12), 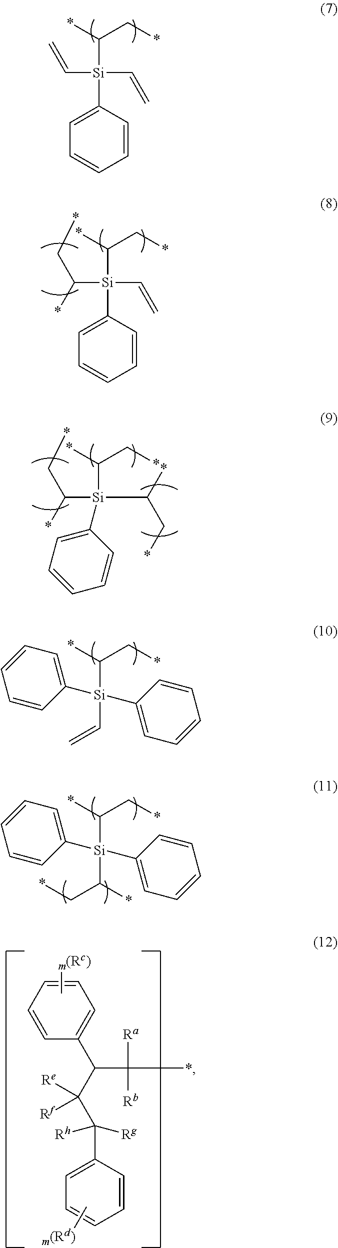
wherein,
J1, J2, J3, K1, and K2 are each independently an integer greater than or equal to 0, but not simultaneously 0, and L1 is an integer greater than or equal to 1; and
10≤J1+J2+J3+L1≤268; or
8≤K1+K2+L1≤212; or
8≤J1+J2+J3+K1+K2+L1≤268.

5. The copolymer according to claim 1, wherein
a weight average molecular weight of the copolymer is between 2,000 and 50,000.

6. A method for preparing the copolymer according to claim 1, comprising:
reacting 80 to 98 parts by weight of phenylvinylsilane and 2 to 20 parts by weight of vinyl-containing compound A at 80° C. to 150° C. for 2 hours to 10 hours.

7. The method according to claim 6, wherein,
the reaction is conducted in a presence of an initiator, a catalyst, or a combination thereof.

8. A resin composition, comprising:
100 parts by weight of the copolymer according to claim 1;
15 to 70 parts by weight of a vinyl-containing polyphenylene ether resin; and
30 to 100 parts by weight of a polyolefin resin.

9. The resin composition according to claim 8, wherein
the vinyl-containing polyphenylene ether resin comprises a vinylbenzyl-terminated polyphenylene ether resin, a methacrylate-terminated polyphenylene ether resin, a allyl-terminated polyphenylene ether resin, or a combination thereof.

10. The resin composition according to claim 9, wherein
the vinylbenzyl-terminated polyphenylene ether resin comprises a structure of formula (13), and/or the methacryl-terminated ate polyphenylene ether resin comprises a structure of formula (14), 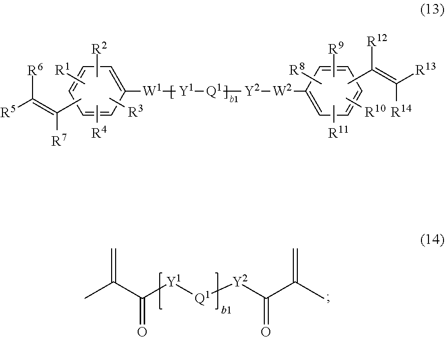
wherein,
R¹ to R¹⁴ are each independently H or —CH₃;
W¹ and W² are each independently a C₁ to C₃ divalent aliphatic group;
b1 is an integer from 0 to 8;
Q¹ comprises any one of structures of formula (B-1) to formula (B-3), or a combination thereof, 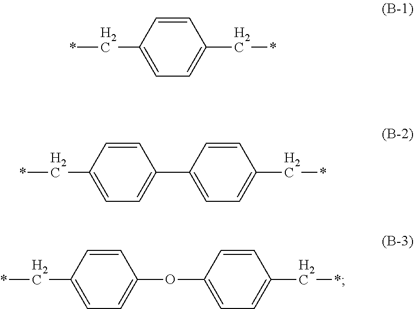
and
Y¹ and Y² each independently comprise a structure of formula (B-4), 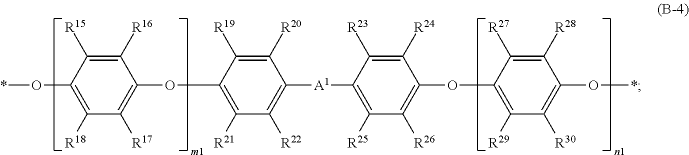
and
wherein,
R¹⁵ to R³⁰ are each independently H or —CH₃;
m1 and n1 are each independently an integer from 1 to 30; and
A¹ is covalent bond, —CH₂—, —CH(CH₃)—, —C(CH₃)₂—, —O—, —S—, —SO₂—, or carbonyl.

11. The resin composition according to claim 8, wherein
the polyolefin resin comprises an unsaturated polyolefin resin, a hydrogenated unsaturated polyolefin resin, or a combination thereof.

12. The resin composition according to claim 8, wherein
the resin composition further comprises a maleimide resin, a maleimide triazine resin, a small molecule vinyl-containing resin, a small molecule vinyl-containing resin prepolymer, a styrene maleic anhydride resin, an epoxy resin, a phenol resin, a benzoxazine resin, a cyanate ester resin, a polyester resin, a polyamide resin, a polyimide resin, or a combination thereof.

13. The resin composition according to claim 8, wherein
the resin composition further comprises an amine curing agent, a flame retardant, an inorganic filler, a curing accelerator, a polymerization inhibitor, a colorant, a solvent, a toughening agent, a silane coupling agent, or a combination thereof.

14. The resin composition according to claim 8, wherein the resin composition has a use for preparing a product, wherein the product comprises a prepreg, a resin film, a laminate, a printed circuit board, or a cured insulator.

15. A product, comprising a prepreg, a resin film, a laminate, a printed circuit board, or a cured insulator, wherein
at least a portion of the product is made from the resin composition according to claim 8.

16. The product according to claim 15, wherein
the product has a glass transition temperature greater than or equal to 175° C. as measured by a method of IPC-TM-650 2.4.24.4.

17. The product according to claim 15, wherein
the product has a peeling strength of copper foil greater than or equal to 3.10 lb/in as measured by a method of IPC-TM-650 2.4.8.

18. The product according to claim 15, wherein
the product has a dielectric constant less than or equal to 3.00 as measured by a method of JIS C2565 at a frequency of 10 GHz.

19. The product according to claim 15, wherein
the product has a dissipation factor less than or equal to 0.00105 measured by a method of JIS C2565 at a frequency of 10 GHz.

20. The product according to claim 15, wherein
the product has a Z-axis ratio of thermal expansion less than or equal to 2.6% as measured by a method of IPC-TM-650 2.4.24.5.
